(19) United States
(12) Patent Application Publication
(10) Pub. No.: US 2026/0293618 A1
(43) Pub. Date: Sep. 24, 2026

(54) PROCESSING METHOD FOR PLATE-SHAPED OBJECT, MANUFACTURING METHOD FOR CHIP, FORMING APPARATUS FOR PROTECTIVE MEMBER, AND PROCESSING APPARATUS FOR PLATE-SHAPED OBJECT

(71) Applicant: DISCO CORPORATION, Tokyo (JP)

(72) Inventor: Takaya OUCHI, Tokyo (JP)

(21) Appl. No.: 19/552,615

(22) Filed: Feb. 27, 2026

(30) Foreign Application Priority Data
Mar. 21, 2025 (JP) 2025-046884
Jan. 8, 2026 (JP) 2026-002330

(51) Int. Cl. H10P 90/00; H10P 58/00; H10P 72/00; H10P 74/20

(52) U.S. Cl. CPC H10P 90/00; H10P 58/00; H10P 72/0428; H10P 74/203

(57) ABSTRACT

A processing method for a plate-shaped object includes forming a protective member on a first surface side of a plate-shaped object having a first surface and a second surface facing a side opposite to the first surface, before or after forming the protective member, treating the protective member or a material used as the protective member, so as to make a volume or a physical property of a freely-selected portion of the protective member different from that of at least another portion, and, after forming and treating the protective member, processing the second surface side of the plate-shaped object such that the plate-shaped object becomes thinner in a state where the first surface side of the plate-shaped object is held via the protective member.

### BACKGROUND OF THE INVENTION

### Field of the Invention

The present invention relates to a processing method for a plate-shaped object, a manufacturing method for a chip, a forming apparatus for a protective member, and a processing apparatus for a plate-shaped object.

### Description of the Related Art

In order to realize a small and lightweight device chip, there have been increasing opportunities to thin a wafer on which a device such as an integrated circuit (IC) is provided on the front surface side. For example, when a protective member is arranged on the front surface side of a wafer, the front surface side of the wafer is held by a chuck table or the like via the protective member, and a processing tool such as a grinding wheel or a polishing pad is brought into contact with the back surface side of the wafer while being rotated, the wafer is processed and made thin (for example, see Japanese Patent Laid-open No. 2009-246098).

### SUMMARY OF THE INVENTION

Incidentally, in the above-mentioned processing methods such as grinding and polishing used for making a plate-shaped object (plate-like member) such as a wafer thin, the thickness of the plate-shaped object is not made uniform as a whole in many cases due to features of the plate-shaped object to be processed, processing tools, a chuck table for holding the plate-shaped object, and the like. Therefore, it has been required to establish a new processing method capable of controlling the thickness of a freely-selected portion (optionally selected portion) of a plate-shaped object that has been processed.

Accordingly, an object of the present invention is to provide a plate-shaped object processing method that can control the thickness of a freely-selected portion of a processed plate-shaped object when the plate-shaped object is made thin, a chip manufacturing method that includes the plate-shaped object processing method, as well as a protective member forming apparatus and a plate-shaped object processing apparatus that are suitable for carrying out these methods.

In accordance with an aspect of the present invention, there is provided a processing method for a plate-shaped object, the processing method including forming a protective member on a first surface side of a plate-shaped object having a first surface and a second surface facing a side opposite to the first surface, before or after forming the protective member, treating the protective member or a material used as the protective member, so as to make a volume or a physical property of a freely-selected portion of the protective member different from that of at least another portion, and, after forming and treating the protective member, processing the second surface side of the plate-shaped object such that the plate-shaped object becomes thinner in a state where the first surface side of the plate-shaped object is held via the protective member.

In accordance with another aspect of the present invention, there is provided a processing method for a plate-shaped object, the processing method including forming a protective member on a first surface side of a plate-shaped object having a first surface and a second surface facing a side opposite to the first surface, before or after forming the protective member, applying energy to a freely-selected portion of the protective member or a corresponding portion of a material used as the protective member, so as to make a volume or a physical property of the freely-selected portion of the protective member different from that of at least another portion, and, after forming the protective member and applying the energy, processing the second surface side of the plate-shaped object such that the plate-shaped object becomes thinner in a state where the first surface side of the plate-shaped object is held via the protective member.

In another aspect of the present invention, the freely-selected portion of the protective member or the portion of the material includes a first region and a second region different from the first region, and, in the application of the energy, energy applied per unit area of the first region is made different from that applied per unit area of the second region.

In another aspect of the invention, the processing method for a plate-shaped object may further include forming a protective member for evaluation on a first surface side of a plate-shaped object for evaluation having a first surface and a second surface facing a side opposite to the first surface, after forming the protective member for evaluation, processing the second surface side of the plate-shaped object for evaluation such that the plate-shaped object for evaluation becomes thinner in a state where the first surface side of the plate-shaped object for evaluation is held via the protective member for evaluation, measuring a thickness of the processed plate-shaped object for evaluation, and determining the freely-selected portion of the protective member or the portion of the material to which the energy is applied, on the basis of a result obtained by measuring the thickness.

In accordance with a further aspect of the present invention, there is provided a manufacturing method for a chip, the manufacturing method including the processing method for a plate-shaped object described above and further including, after processing the second surface side of the plate-shaped object, manufacturing a chip by dividing the plate-shaped object.

In accordance with a still further aspect of the present invention, there is provided a forming apparatus for a protective member, the forming apparatus including a protective member forming unit that forms a protective member on a first surface side of a plate-shaped object in a state where a second surface side of the plate-shaped object having a first surface and a second surface facing the side opposite to the first surface is held, an energy applying unit that applies energy to a freely-selected portion of the protective member so as to make a volume or a physical property of the freely-selected portion of the protective member different from that of at least another portion in a state where the second surface side of the plate-shaped object on the first surface side of which the protective member is formed is held, and a controller that controls an operation of at least the energy applying unit, in which the controller stores a condition for applying energy to the freely-selected portion of the protective member and controls an operation of the energy applying unit on the basis of the stored condition to apply energy to the freely-selected portion of the protective member.

In accordance with one of the other aspects of the present invention, there is provided a processing apparatus for a plate-shaped object, the processing apparatus including an energy applying unit that applies energy to a freely-selected portion of a protective member provided on a first surface side of a plate-shaped object, so as to make a volume or a physical property of the freely-selected portion of the protective member different from that of at least another portion in a state where a second surface side of the plate-shaped object having a first surface and a second surface facing the side opposite to the first surface is held, a processing unit that processes the second surface side of the plate-shaped object such that the plate-shaped object becomes thinner in a state where the first surface side of the plate-shaped object is held via the protective member, and a controller that controls an operation of at least the energy applying unit, in which the controller stores a condition for applying energy to the freely-selected portion of the protective member and controls an operation of the energy applying unit on the basis of the stored condition to apply energy to the freely-selected portion of the protective member.

In another aspect of the present invention, there may further be provided a protective member forming unit that forms a protective member on the first surface side of the plate-shaped object in a state where the second surface side of the plate-shaped object is held.

According to the processing method for a plate-shaped object according to an aspect of the present invention, the processing method for a plate-shaped object according to another aspect, and the manufacturing method for a chip according to a further aspect, the protective member or the material used as the protective member is treated, or energy is applied to the freely-selected portion of the protective member and the corresponding portion of the material used as the protective member, so as to make the volume or the physical property of the freely-selected portion of the protective member different from that of at least the other portion.

Thus, if the plate-shaped object is processed to become thinner in a state where the plate-shaped object is held via the protective member, the thickness of the processed plate-shaped object at a position corresponding to the freely-selected portion of the protective member is made different from the thickness obtained in a case where the plate-shaped object is processed in a state where the above-described treatment is not performed on the protective member or in a state where no energy is applied to the protective member.

That is, according to the processing method for a plate-shaped object according to an aspect of the present invention, the processing method for a plate-shaped object according to another aspect, and the manufacturing method for a chip according to a further aspect, when the plate-shaped object is thinned, the thickness of the freely-selected portion of the processed plate-shaped object can be controlled. In addition, according to the forming apparatus for a protective member according to still another aspect of the present invention and the processing apparatus for a plate-shaped object according to another aspect, these methods can appropriately be carried out.

The above and other objects, features and advantages of the present invention and the manner of realizing them will become more apparent, and the invention itself will best be understood from a study of the following description and appended claims with reference to the attached drawings showing a preferred embodiment of the present invention.

### BRIEF DESCRIPTION OF THE DRAWINGS

FIG. 1 is a perspective view for schematically depicting an example of a plate-shaped object;

FIG. 2 is a flowchart for schematically depicting an outline of a manufacturing method for a chip, the manufacturing method including a processing method for a plate-shaped object;

FIG. 3 is a flowchart for schematically depicting details of a procedure related to evaluation of the plate-shaped object;

FIG. 4 is a flowchart for schematically depicting details of a procedure related to processing of the plate-shaped object;

FIG. 5 is a side view for schematically depicting portions related to formation of a protective member in a processing apparatus for a plate-shaped object;

FIG. 6 is a cross-sectional view for schematically depicting portions related to processing of the plate-shaped object in the processing apparatus for a plate-shaped object;

FIG. 7 is a plan view for schematically depicting the distribution of the thickness of a plate-shaped object for evaluation that has been processed;

FIG. 8 is a plan view for schematically depicting an example of a mask used when the protective member is irradiated with ultraviolet rays;

FIG. 9 is a side view for schematically depicting portions related to application of energy in the processing apparatus for a plate-shaped object;

FIG. 10 is a plan view for schematically depicting the distribution of the thickness of the processed plate-shaped object;

FIG. 11 is a cross-sectional view for schematically depicting a state in which the plate-shaped object is divided;

FIG. 12 is a side view for schematically depicting portions related to formation of the protective member in a processing apparatus for a plate-shaped object according to a modified example;

FIG. 13 is a cross-sectional view for schematically depicting portions related to processing of the plate-shaped object in a processing apparatus for a plate-shaped object according to a modified example;

FIG. 14 is a plan view for schematically depicting the distribution of the thickness of the processed plate-shaped object formed in a rectangular shape in plan view;

FIG. 15 is a plan view for schematically depicting a first mask used when the protective member is irradiated with ultraviolet rays;

FIG. 16 is a plan view for schematically depicting a second mask used when the protective member is irradiated with ultraviolet rays;

FIG. 17 is a plan view for schematically depicting a third mask used when the protective member is irradiated with ultraviolet rays;

FIG. 18 is a plan view for schematically depicting the distribution of the thickness of the protective member that has been irradiated with ultraviolet rays with use of the first mask;

FIG. 19 is a plan view for schematically depicting the distribution of the thickness of the protective member that has further been irradiated with ultraviolet rays with use of the second mask;

FIG. 20 is a plan view for schematically depicting the distribution of the thickness of the protective member that has further been irradiated with ultraviolet rays with use of the third mask;

FIG. 21 is a plan view for schematically depicting a state in which the mask is displaced relative to the protective member when the protective member is irradiated with ultraviolet rays;

FIG. 22 is a cross-sectional view for schematically depicting a plate-shaped object in which a bump electrode having an uneven structure is arranged on the first surface side;

FIG. 23 is a cross-sectional view for schematically depicting a structure of a chuck table according to a modified example; and

FIG. 24 is a plan view for schematically depicting the distribution of the thickness of the plate-shaped object that has been processed by a method according to a modified example.

### DETAILED DESCRIPTION OF THE PREFERRED EMBODIMENT

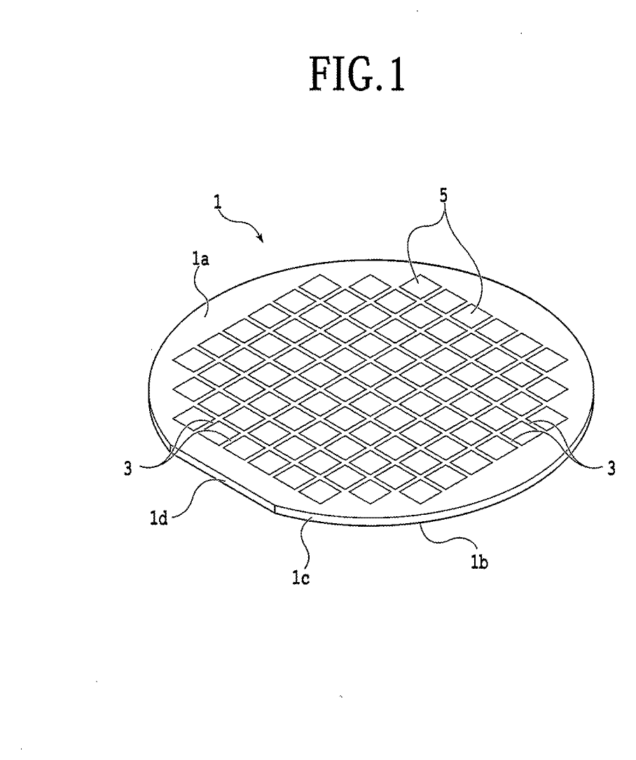

Hereinafter, an embodiment of the present invention will be described with reference to the accompanying drawings. FIG. 1 is a perspective view for schematically depicting an example of a plate-shaped object 1 used in a processing method for a plate-shaped object and a manufacturing method for a chip (hereinafter, referred to as a "manufacturing method for a chip and the like") according to the present embodiment.

The plate-shaped object 1 depicted in FIG. 1 is a disk-like wafer including a semiconductor such as silicon (Si) having crystallinity as a main material, and has a circular first surface (front surface) 1a and a circular second surface (back surface) 1b facing the side opposite to the first surface 1a. The outer edge of the first surface 1a and the outer edge of the second surface 1b are connected to each other via a side surface 1c.

A cutout portion 1d called an orientation flat is provided at a part of the side surface 1c of the plate-shaped object 1 in order to indicate the orientation of a crystal contained in the material configuring the plate-shaped object 1. The cutout portion 1d of the present embodiment is provided along, for example, a chord of a circle overlapped with the outer edge of the first surface 1a or the second surface 1b, and is formed in a substantially linear shape when viewed from a position facing the first surface 1a or the second surface 1b. It should be noted that the plate-shaped object 1 may be provided with a cutout portion called a notch instead of the orientation flat.

A region of the plate-shaped object 1 on the first surface 1a side is partitioned into a plurality of small regions by a plurality of scheduled division lines (streets) 3 that are linearly set. Further, a device 5 typified by an IC is provided in each small region. A plurality of device chips, each of which is provided with the device 5, are obtained by dividing the plate-shaped object 1 at all the scheduled division lines 3.

It should be noted that, in the present embodiment, the disk-like wafer including a semiconductor such as silicon having crystallinity as a main material is exemplified as the plate-shaped object 1, but the material, shape, structure, size, and the like of the plate-shaped object 1 are not limited to the exemplified manners. For example, a substrate mainly containing a material such as another semiconductor, ceramics, resin, or metal and the like can be used as the plate-shaped object 1. Similarly, the types, number, shapes, structures, sizes, arrangements, and the like of the devices 5 are not limited to the exemplified manners. The plate-shaped object 1 is not provided with the devices 5 in some cases.

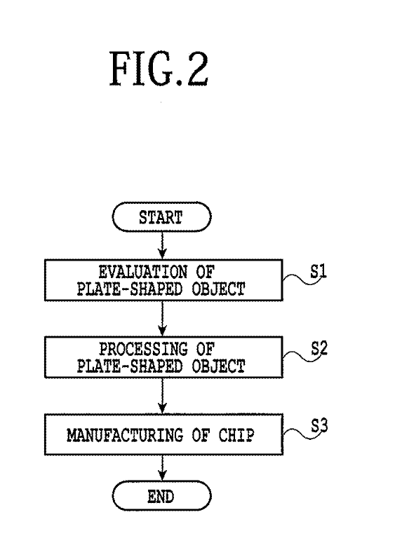

FIG. 2 is a flowchart for schematically depicting an outline of a manufacturing method for a chip, the manufacturing method including the processing method for a plate-shaped object, according to the present embodiment. In the processing method for a plate-shaped object according to the present embodiment, as depicted in FIG. 2, characteristics related to processing of a plate-shaped object (a plate-shaped object for evaluation) having features similar to those of the plate-shaped object 1 to be processed are first evaluated (evaluation step S1).

After the evaluation of the plate-shaped object is performed, the plate-shaped object 1, which is the material of an actual product, is processed using the result of the evaluation (processing step S2). Accordingly, it is possible to, for example, enhance the uniformity of the thickness in the processed plate-shaped object 1 by controlling the thickness of a freely-selected portion of the processed plate-shaped object 1. When the processing of the plate-shaped object 1 is completed, the processing method for a plate-shaped object according to the present embodiment is finished.

On the other hand, in the above-described chip manufacturing method including the processing method for a plate-shaped object, manufacturing of a chip is subsequently performed (chip manufacturing step S3). Specifically, the processed plate-shaped object 1 is divided (cut) at all the scheduled division lines 3. Accordingly, a plurality of chips (device chips) are obtained.

It should be noted that, in a case where a plurality of plate-shaped objects 1 of the same type are processed under equivalent conditions, the above-described evaluation is performed before at least the first plate-shaped object 1 is processed. When the second and subsequent plate-shaped objects 1 are processed, the result of the evaluation performed before the first plate-shaped object 1 is processed can be used, so that the evaluation immediately before the second and subsequent plate-shaped objects 1 are processed need not be performed. As described above, the evaluation of the plate-shaped object is omitted depending on the situation in some cases.

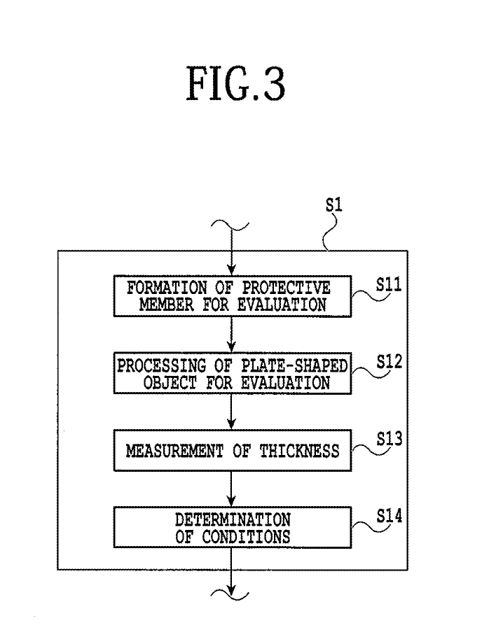

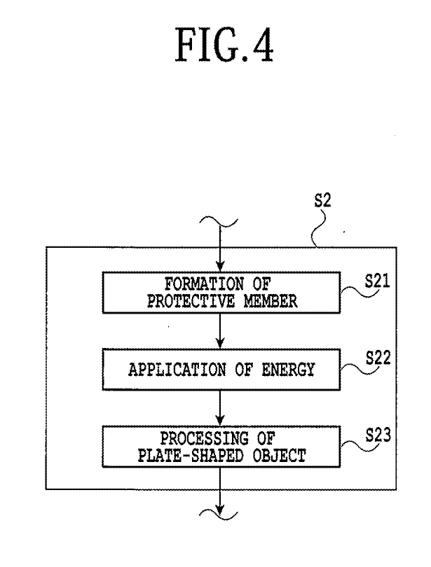

FIG. 3 is a flowchart for schematically depicting details of a "procedure related to the evaluation of the plate-shaped object (evaluation step S1)," and FIG. 4 is a flowchart for schematically depicting details of a "procedure related to the processing of the plate-shaped object (processing step S2)." In the "procedure of the evaluation of the plate-shaped object," as depicted in FIG. 3, a protective member (protective member for evaluation) is formed on the plate-shaped object for evaluation (formation step for protective member for evaluation S11).

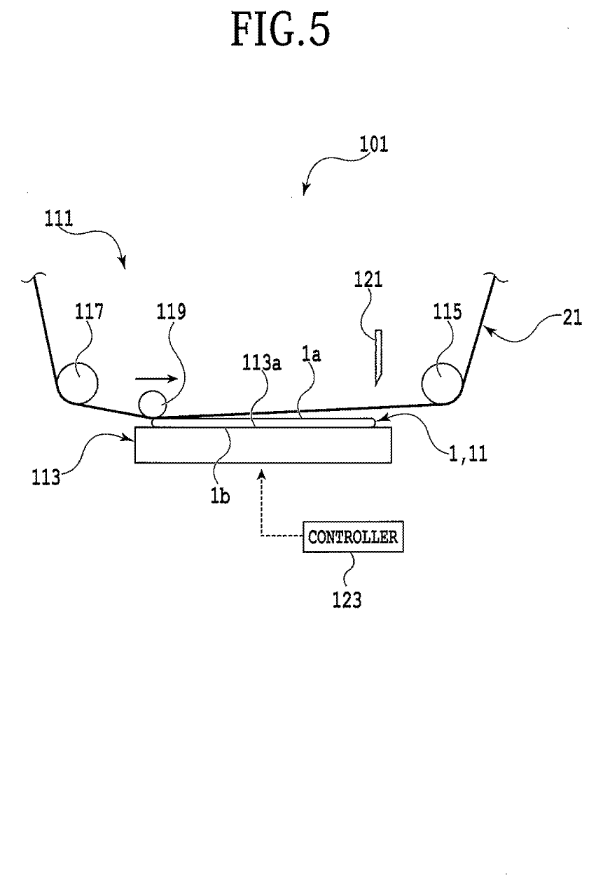

FIG. 5 is a side view for schematically depicting portions related to formation of the protective member in a processing apparatus 101 of a plate-shaped object including a forming apparatus for a protective member according to the present embodiment. As depicted in FIG. 5, the processing apparatus 101 of a plate-shaped object (hereinafter, referred to as a "processing apparatus 101") includes a protective member forming unit 111 that can form the protective member or the protective member for evaluation in the plate-shaped object 1 or a plate-shaped object for evaluation 11.

The protective member forming unit 111 is provided with a support table 113 configured to be capable of supporting the plate-shaped object 1 or the plate-shaped object for evaluation 11 from the lower side. The plate-shaped object 1 or the plate-shaped object for evaluation 11 is placed on an upper surface 113a of the support table 113. It should be noted that the features of the plate-shaped object for evaluation 11 used in the present embodiment are substantially the same as those of the plate-shaped object 1. Accordingly, the portions of the plate-shaped object for evaluation 11 are denoted by the same reference numerals as the corresponding portions of the plate-shaped object 1, and the duplicate description thereof is omitted here.

A support roller (not illustrated) for supporting a belt-like tape (material) 21 wound in a cylindrical shape and a winding roller (not illustrated) for winding the tape 21 fed from the support roller are arranged above the support table 113. The tape 21 is the material of the protective member and the protective member for evaluation.

In the present embodiment, an ultraviolet-curable adhesive tape provided with a base material layer made of resin and an adhesive layer (bonding layer) provided on the surface of the base material layer is used as the tape 21. That is, the adhesive layer of the tape 21 is made of ultraviolet-curable resin typified by acrylic resin and epoxy resin. In addition, the base material layer of the tape 21 is made of resin such as polyolefin or polyvinyl chloride. It should be noted that the thickness of the base material layer is, for example, 20 to 200 μm, typically, 50 μm, and the thickness of the adhesive layer is, for example, 10 to 100 μm, typically, 30 μm.

At positions on the downstream side of the support roller and the upstream side of the winding roller, a guide roller 115 and a guide roller 117 for guiding the tape 21 fed from the support roller to the upper side of the support table 113 are arranged in such a manner as to sandwich a space above the support table 113.

The tape 21 is fed from the support roller such that the base material layer thereof is brought into contact with the guide roller 115 and the guide roller 117 and the adhesive layer thereof faces down above the support table 113. A pressing roller 119 capable of applying a pressure downward from above the tape 21 to the tape 21 guided to the upper side of the support table 113 is arranged at a position between the guide roller 115 and the guide roller 117.

The pressing roller 119 is supported by, for example, a roller moving mechanism (not illustrated) including ball screws. With power generated by the roller moving mechanism, the pressing roller 119 moves in a direction (horizontal direction) substantially parallel to the upper surface 113a of the support table 113 and a direction (vertical direction) substantially perpendicular to the upper surface 113a.

In addition, a tape cutting mechanism is arranged above the support table 113 in such a manner as not to interfere with the guide roller 115, the guide roller 117, and the pressing roller 119. The tape cutting mechanism has a blade 121 suitable for cutting the tape 21 and lowers the blade 121 and moves the blade 121 along the edge of the plate-shaped object 1 or the edge of the plate-shaped object for evaluation 11. Accordingly, the tape 21 is cut in accordance with the shape of the plate-shaped object 1 or the plate-shaped object for evaluation 11.

A controller (control unit) 123 of the processing apparatus 101 is connected to each portion of the above-described protective member forming unit 111. The controller 123 includes a computer including, for example, a processing device and a storage device, and controls an operation and the like of each portion of the processing apparatus 101 including the protective member forming unit 111 such that the above-described plate-shaped object 1 is appropriately processed.

The processing device is typically a central processing unit (CPU), and performs various kinds of processing necessary for controlling each portion of the processing apparatus 101. The storage device includes, for example, a main storage device such as a dynamic random access memory (DRAM) and an auxiliary storage device such as a hard disk drive and a flash memory. The functions of the controller 123 are realized by, for example, the processing device operating according to a program stored in the storage device.

When the protective member for evaluation is formed on the plate-shaped object for evaluation 11, the plate-shaped object for evaluation 11 is placed on the support table 113 in such a manner that the second surface 1b of the plate-shaped object for evaluation 11 is brought into contact with the upper surface 113a of the support table 113. Accordingly, the plate-shaped object for evaluation 11 is supported by the support table 113 in a state where the first surface 1a faces upward.

When the plate-shaped object for evaluation 11 is supported by the support table 113, the tape 21 fed from the support roller is guided by the pair of the guide roller 115 and the guide roller 117 and arranged above the plate-shaped object for evaluation 11. Thereafter, the roller moving mechanism lowers the pressing roller 119 between the guide roller 115 and the guide roller 117.

Accordingly, the pressing roller 119 is brought into contact with the tape 21 arranged above the plate-shaped object for evaluation 11, and a part of the tape 21 closely adheres to the first surface 1a of the plate-shaped object for evaluation 11 by a downward pressure applied from the pressing roller 119. As depicted in FIG. 5, when the roller moving mechanism moves the pressing roller 119 in a direction substantially parallel to the upper surface 113a of the support table 113 in a state where the height of the pressing roller 119 is maintained, the tape 21 is stuck to the whole of the first surface 1a of the plate-shaped object for evaluation 11.

When the tape 21 is stuck to the plate-shaped object for evaluation 11, the tape cutting mechanism lowers the blade 121 and moves it along the edge of the plate-shaped object for evaluation 11. Accordingly, the tape 21 is cut along the edge of the plate-shaped object for evaluation 11, and the protective member for evaluation is formed on the first surface 1a side of the plate-shaped object for evaluation 11. As described above, the tape 21 used when the protective member for evaluation is formed is also used when the protective member of the plate-shaped object 1 is formed. That is, the features of the protective member of the plate-shaped object 1 are substantially the same as those of the protective member for evaluation.

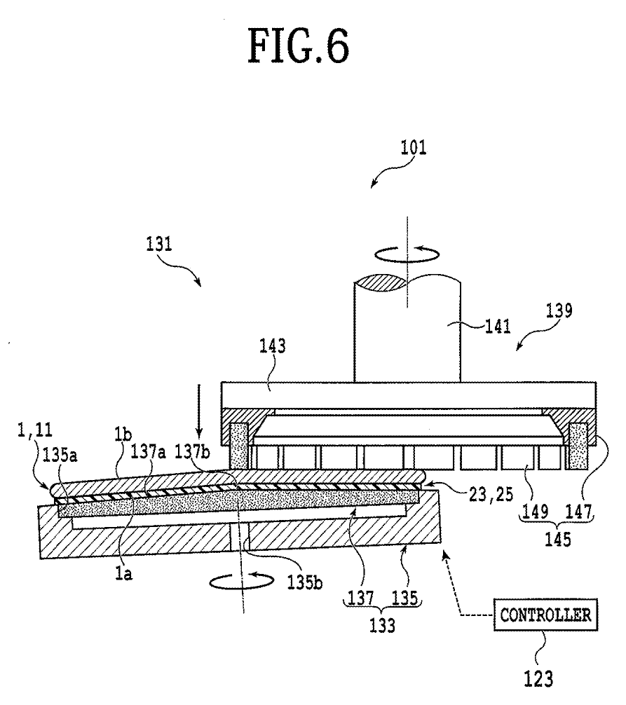

After the protective member for evaluation is provided in the plate-shaped object for evaluation 11, the plate-shaped object for evaluation 11 is processed to be thinned (processing step for plate-shaped object for evaluation S12). In the present embodiment, the second surface 1b of the plate-shaped object for evaluation 11 is ground (in-feed grinding). FIG. 6 is a cross-sectional view for schematically depicting portions related to processing of the plate-shaped object 1 or the plate-shaped object for evaluation 11 in the processing apparatus 101.

As depicted in FIG. 6, the processing apparatus 101 of the present embodiment includes a grinding unit (processing unit) 131 capable of grinding the plate-shaped object 1 or the plate-shaped object for evaluation 11. It should be noted that the grinding unit 131 may be omitted in the forming apparatus for the protective member according to the present embodiment.

The grinding unit 131 is provided with a chuck table 133 configured to be capable of holding the plate-shaped object 1 or the plate-shaped object for evaluation 11. The chuck table 133 includes, for example, a disk-like frame body 135 made of ceramics and the like. A recessed portion 135a having a circular opening at the upper end is formed on the upper surface side of the frame body 135, and a holding plate 137 made of ceramics and the like and configured in a porous disk shape is fixed to the recessed portion 135a.

An upper surface 137a of the holding plate 137 is configured in a shape corresponding to, for example, a side surface of a cone, and functions as a holding surface for holding the plate-shaped object 1 or the plate-shaped object for evaluation 11. It should be noted that the difference of the height (height difference) between a center 137b of the upper surface 137a of the holding plate 137 corresponding to the apex of the cone and the outer edge of the upper surface 137a of the holding plate 137 is approximately 10 to 30 μm. In the present embodiment, a protective member 23 formed on the plate-shaped object 1 or a protective member for evaluation 25 formed on the plate-shaped object for evaluation 11 is brought into contact with the upper surface 137a of the holding plate 137.

The lower surface side of the holding plate 137 is connected to a suction source (not illustrated) such as an ejector via a flow path 135b provided inside the frame body 135, a valve (not illustrated) arranged outside the frame body 135, and the like. Therefore, when the valve is opened and a negative pressure of the suction source is applied in a state where the protective member 23 or the protective member for evaluation 25 is brought into contact with the upper surface 137a of the holding plate 137, the protective member 23 or the protective member for evaluation 25 is sucked by the chuck table 133. As a result, the plate-shaped object 1 or the plate-shaped object for evaluation 11 is held by the chuck table 133 in a state where the second surface 1b is exposed upward.

A rotation drive source (not illustrated) such as a motor is coupled to a lower portion of the frame body 135. The chuck table 133 is rotated about an axis along the vertical direction or an axis slightly inclined with respect to the vertical direction, by power generated by the rotation drive source, such that the center 137b of the upper surface 137a becomes the center of rotation. In addition, the frame body 135 is supported by a chuck table moving mechanism (not illustrated) including ball screws, and the chuck table 133 is moved in the horizontal direction by power generated by the chuck table moving mechanism.

A spindle mechanism 139 for grinding is arranged at a position above the chuck table 133. The spindle mechanism 139 includes, for example, a cylindrical spindle housing (not illustrated). A columnar spindle 141 is housed in a space inside the spindle housing. For example, a disk-like mount 143 is provided at the lower end of the spindle 141. An annular grinding wheel (tool for grinding) 145 having a diameter substantially equal to that of the mount 143 is fixed to a lower surface of the mount 143 by bolts (not illustrated) and the like.

The grinding wheel 145 includes an annular wheel base 147 made of metal such as stainless steel or aluminum. A plurality of grinding whetstones 149 are fixed to an annular lower surface of the wheel base 147 along the circumferential direction of the wheel base 147. That is, the plurality of grinding whetstones 149 are annularly arranged. Each of the grinding whetstones 149 has, for example, a structure in which abrasive grains of diamond or the like are dispersed in a bonding agent containing resin and the like.

A rotation drive source (not illustrated) such as a motor is coupled to the upper end of the spindle 141. The grinding wheel 145 is rotated about an axis along the vertical direction or an axis slightly inclined with respect to the vertical direction, by the power generated by the rotation drive source. A spindle housing is supported by, for example, a spindle moving mechanism (not illustrated) including ball screws, and the spindle mechanism 139 is moved in the vertical direction by power generated by the spindle moving mechanism.

A grinding liquid supply nozzle (not illustrated) capable of supplying liquid for grinding (grinding liquid) such as water to a part where the plate-shaped object 1 or the plate-shaped object for evaluation 11 and the grinding whetstones 149 are brought into contact with each other is arranged near the grinding wheel 145. It should be noted that, instead of the grinding liquid supply nozzle or together with the grinding liquid supply nozzle, a grinding liquid supply port used for supplying the liquid may be provided in the grinding wheel 145 or the like.

When the plate-shaped object for evaluation 11 is ground, the plate-shaped object for evaluation 11 is placed on the chuck table 133 such that the protective member for evaluation 25 is brought into contact with the upper surface 137a of the chuck table 133. Next, the valve is opened, and the negative pressure of the suction source is applied to the upper surface 137a of the holding plate 137. Accordingly, the protective member for evaluation 25 is sucked by the upper surface 137a of the holding plate 137 in a state where the second surface 1b of the plate-shaped object for evaluation 11 is exposed upward. That is, the first surface 1a side of the plate-shaped object for evaluation 11 is held by the chuck table 133 via the protective member for evaluation 25.

After the first surface 1a side of the plate-shaped object for evaluation 11 is held via the protective member for evaluation 25, the second surface 1b side of the plate-shaped object for evaluation 11 is ground. Specifically, the chuck table 133 is moved directly below the spindle mechanism 139. More specifically, the position of the chuck table 133 in the horizontal direction is adjusted by the chuck table moving mechanism such that the plurality of grinding whetstones 149 pass through a space directly above the center 137b of the chuck table 133 in a case where the grinding wheel 145 is rotated.

Thereafter, the chuck table 133 and the grinding wheel 145 are each rotated, and the spindle mechanism 139 is lowered. That is, the grinding wheel 145 and the plate-shaped object for evaluation 11 are moved relative to each other in a direction intersecting the second surface 1b of the plate-shaped object for evaluation 11 while being mutually rotated. At this time, the liquid for grinding is supplied from the grinding liquid supply nozzle to the plate-shaped object for evaluation 11, the grinding whetstones 149, and the like. Then, as depicted in FIG. 6, the grinding whetstones 149 are brought into contact with the plate-shaped object for evaluation 11 from the second surface 1b side, and grinding of the plate-shaped object for evaluation 11 is started.

It should be noted that there are no significant limitations on specific conditions adopted when the plate-shaped object for evaluation 11 is ground, such as the number of revolutions of the chuck table 133 per unit time, the number of revolutions of the grinding wheel 145 per unit time, the speed of lowering the spindle mechanism 139 (grinding feed speed), and the like, but conditions that can be regarded as substantially the same as those adopted when grinding of a subsequent plate-shaped object 1 is performed are preferably adopted.

Thus, the thickness of a freely-selected portion of the processed plate-shaped object 1 can be controlled with extremely high accuracy. When the plate-shaped object for evaluation 11 becomes thinner up to a preset thickness, the spindle mechanism 139 is lifted, and the grinding whetstones 149 are separated from the plate-shaped object for evaluation 11. Accordingly, the grinding of the plate-shaped object for evaluation 11 is finished.

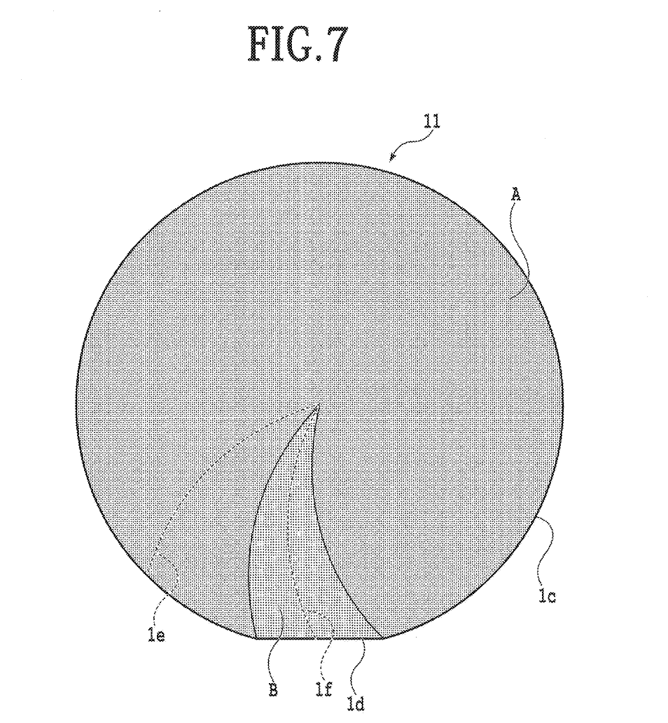

After the processing of the plate-shaped object for evaluation 11 is finished, the thickness of the processed plate-shaped object for evaluation 11 is measured (thickness measurement step S13). In the present embodiment, for example, after the protective member for evaluation 25 is removed from the plate-shaped object for evaluation 11, the distribution of the thickness of the plate-shaped object for evaluation 11 is measured by a thickness distribution measurement device outside the processing apparatus 101. FIG. 7 is a plan view for schematically depicting the distribution of the thickness of the processed plate-shaped object for evaluation 11. It should be noted that, in FIG. 7, hatching according to the thickness of the plate-shaped object for evaluation 11 is applied.

The plate-shaped object for evaluation 11 according to the present embodiment has the linear cutout portion 1d called an orientation flat, and the thickness of a portion B including the cutout portion 1d is smaller than the thickness of another portion A. This is because there is a difference between the length of a to-be-ground region 1e in the portion A with which the plurality of grinding whetstones 149 are brought into contact at one time and the length of a to-be-ground region 1f in the portion B with which the plurality of grinding whetstones 149 are brought into contact at another time.

Since the length of the to-be-ground region 1f in the portion B in which the cutout portion 1d is present is shorter than the length of the to-be-ground region 1e in the other portion A, the grinding load in the portion B is smaller than that in the portion A. As a result, the grinding of the plate-shaped object for evaluation 11 more easily progresses in the portion B than in the portion A, and the portion B becomes thinner than the portion A. The difference in thickness between the portion A and the portion B is approximately 0.1 to 3 μm, typically, 1 μm, although it differs depending on grinding conditions and the like.

It should be noted that, although the distribution of the thickness of the plate-shaped object for evaluation 11 is measured by the thickness distribution measurement device outside the processing apparatus 101 in the present embodiment, the distribution of the thickness of the plate-shaped object for evaluation 11 may be measured by, for example, a thickness measurement device or the like provided in the grinding unit 131 in the processing apparatus 101. In addition, in a case where the thickness of the protective member for evaluation 25 can be regarded as uniform as a whole, the distribution of the thickness of the plate-shaped object for evaluation 11 in a state where the protective member for evaluation 25 is not removed (the sum of the thicknesses of the plate-shaped object for evaluation 11 and the protective member for evaluation 25) may be measured.

When information regarding the thickness of the processed plate-shaped object for evaluation 11 is obtained, it is possible to assume an ideal protective member 23 to be used when the plate-shaped object 1, which is the material of an actual product, is processed. For example, in a case where the uniformity of the thickness of the processed plate-shaped object 1 is to be enhanced, the protective member 23 in which a portion corresponding to the portion B (a portion directly below the portion B) is thinner than a portion corresponding to the portion A (a portion directly below the portion A) is ideal. According to such an ideal protective member 23, it becomes difficult to progress the grinding in the portion B as compared with a case where a protective member having a uniform thickness is used, and thus, the uniformity of the thickness of the processed plate-shaped object 1 is enhanced.

In addition, a protective member 23 in which a portion corresponding to the portion B (a portion directly below the portion B) is softer than a portion corresponding to the portion A (a portion directly below the portion A) is also ideal. According to such an ideal protective member 23, the relatively soft portion easily shrinks due to a load applied when grinding is performed, and as a result, it becomes difficult to progress the grinding in the portion B as compared with a case where a protective member having uniform hardness is used, so that the uniformity of the thickness of the processed plate-shaped object 1 is enhanced.

Thus, in the manufacturing method for a chip and the like according to the present embodiment, energy is applied to a freely-selected portion of the protective member 23 so as to make it possible to realize the above-described ideal protective member 23 or the protective member 23 close thereto before the plate-shaped object 1, which is the material of an actual product, is processed. Further, as preparation for this, after the thickness of the plate-shaped object for evaluation 11 is measured, various conditions related to application of the energy, including the portion (position) of the protective member 23 to which the energy is applied, are determined on the basis of the result of the measurement (application condition determination step S14).

In the present embodiment, ultraviolet rays (ultraviolet light) whose wavelength is approximately 10 to 400 nm are assumed as the energy to be applied to the protective member 23, and the ultraviolet-curable tape 21 provided with an adhesive layer made of ultraviolet-curable resin is used as the material of the protective member 23. For example, when the target portion of the protective member 23 is irradiated with ultraviolet rays, curing of the resin configuring the adhesive layer advances, the volume of the target portion is reduced, and the target portion of the protective member 23 becomes thinner.

Thus, by appropriately determining conditions such as a portion (position) that is irradiated with ultraviolet rays as energy and the amount of ultraviolet rays applied as energy (the intensity of ultraviolet rays and duration of irradiation), the above-described ideal protective member 23 or the protective member 23 close thereto can be realized by making the portion corresponding to the portion B of the protective member 23 thinner than the portion corresponding to the portion A.

For example, in a case where the portion B is thinner than the portion A by 1 μm in the processed plate-shaped object for evaluation 11, the conditions under which the energy is applied, that is, the conditions related to irradiation with ultraviolet rays, are determined such that the protective member 23 in which the portion corresponding to the portion B is thicker than the portion corresponding to the portion A by 1 μm can be realized. The conditions thus determined are, for example, stored in the storage device of the controller 123 and used later when the protective member 23 is irradiated with ultraviolet rays (when energy is applied).

After the "procedure related to the evaluation of the plate-shaped object" is finished and various conditions related to the application of energy are determined, the "procedure related to the processing of the plate-shaped object" is subsequently executed. Specifically, as depicted in FIG. 4, the protective member 23 is formed on the first surface 1a side of the plate-shaped object 1, which is the material of an actual product (protective member formation step S21).

The formation of the protective member 23 is performed using the protective member forming unit 111 depicted in FIG. 5, as in the formation of the protective member for evaluation 25. It should be noted that, since the detailed procedure related to the formation of the protective member 23 and the like are substantially the same as the procedure related to the formation of the protective member for evaluation 25 and like, the duplicate description thereof is omitted here.

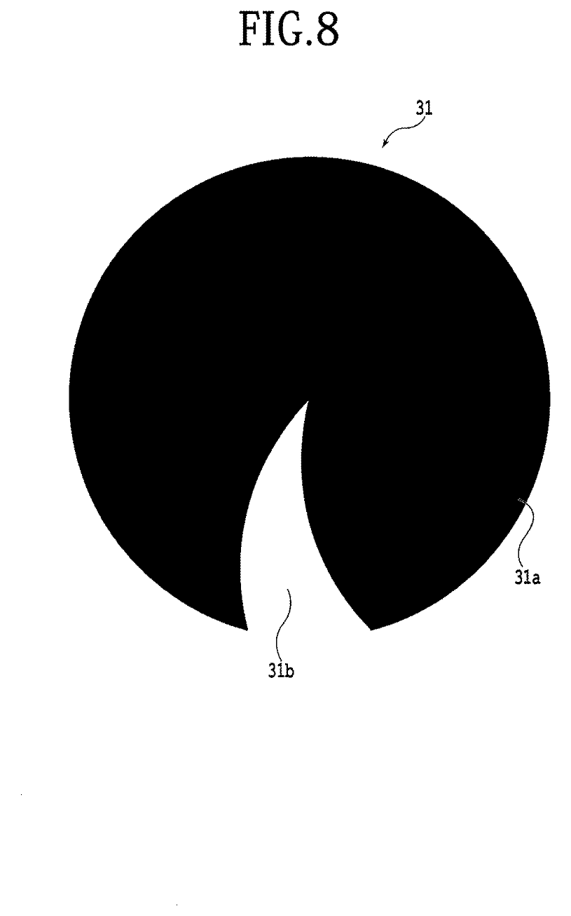

After the protective member 23 is formed on the first surface 1a side of the plate-shaped object 1, energy is applied to the protective member 23 under the above-described conditions (energy application step 22). FIG. 8 is a plan view for schematically depicting an example of a mask 31 used when the protective member 23 is irradiated with ultraviolet rays as energy.

As depicted in FIG. 8, the mask 31 has, for example, a shielding portion 31a that does not substantially transmit target ultraviolet rays. That is, the material, thickness, and the like of the shielding portion 31a are selected so as to be capable of blocking the target ultraviolet rays. In addition, the shielding portion 31a has a shape corresponding to the portion A (a shape capable of covering, at least, the portion A) such that the portion corresponding to the portion A is not exposed to ultraviolet rays when the protective member 23 is irradiated with ultraviolet rays.

Further, the mask 31 has a transmission portion 31b having a shape corresponding to the portion B such that the portion corresponding to the portion B is exposed to ultraviolet rays when the protective member 23 is irradiated with ultraviolet rays. The transmission portion 31b is typically a recessed portion, a cutout portion, or the like, at least a part of the outer edge of which is defined by the shielding portion 31a. However, the transmission portion 31b may include a member whose material, thickness, and the like are selected so as to transmit the target ultraviolet rays. When the mask 31 is used, only the portion corresponding to the portion B can be irradiated with ultraviolet rays.

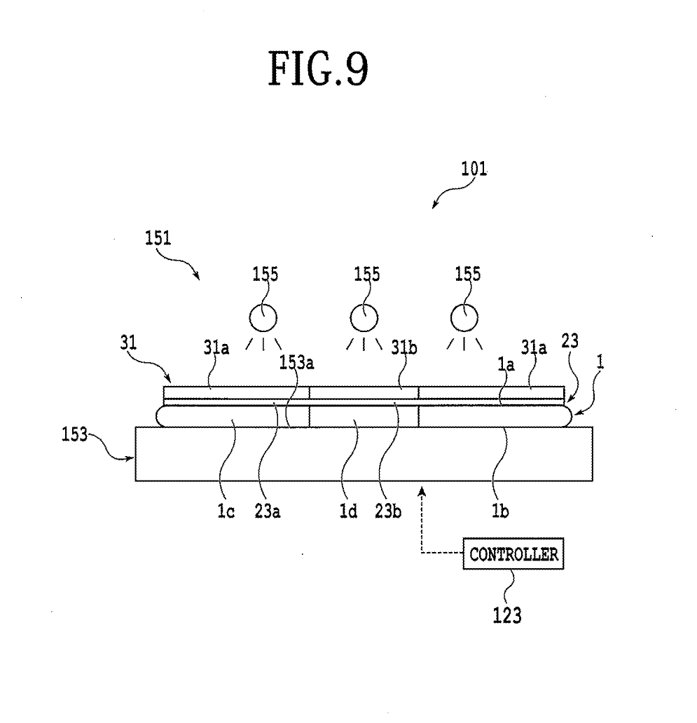

FIG. 9 is a side view for schematically depicting portions related to application of energy (irradiation with ultraviolet rays) in the processing apparatus 101. As depicted in FIG. 9, the processing apparatus 101 includes an ultraviolet irradiation unit (energy applying unit) 151 capable of irradiating the protective member 23 with ultraviolet rays as energy. The ultraviolet irradiation unit 151 is provided with a support table 153 configured to be capable of supporting the plate-shaped object 1 from the lower side. The plate-shaped object 1 is placed on an upper surface 153a of the support table 153 such that the first surface 1a side faces upward.

Light sources 155 capable of irradiating the protective member 23 formed on the plate-shaped object 1 on the support table 153 with ultraviolet rays are arranged above the support table 153. The light sources 155 include, for example, high-pressure mercury lamps, ultraviolet lamps such as metal halide lamps, or ultraviolet light emitting diodes (LEDs), and are configured to be capable of irradiating substantially the entire protective member 23 with ultraviolet rays.

When the protective member 23 is irradiated with ultraviolet rays as energy, the plate-shaped object 1 is placed on the support table 153 such that the second surface 1b of the plate-shaped object 1 is brought into contact with the upper surface 153a of the support table 153. In addition, the above-described mask 31 is overlapped with the protective member 23 formed on the first surface 1a side of the plate-shaped object 1.

It should be noted that the position of the mask 31 is adjusted such that the shielding portion 31a of the mask 31 is overlapped directly above a portion 23a of the protective member 23 corresponding to the portion A of the plate-shaped object 1 and that the transmission portion 31b of the mask 31 is overlapped directly above a portion 23b of the protective member 23 corresponding to the portion B of the plate-shaped object 1. Thereafter, when ultraviolet rays are emitted from the light sources 155, a part thereof reaches the portion 23b of the protective member 23, and curing of the ultraviolet-curable resin configuring the adhesive layer progresses in the portion 23b of the protective member 23.

It should be noted that, at this time, the controller 123 controls an operation of the ultraviolet irradiation unit 151 on the basis of the conditions related to application of energy stored in the storage device. For example, the controller 123 controls the intensity of the ultraviolet rays emitted by the light sources 155, the period of time during which the light sources 155 emit the ultraviolet rays, and the like on the basis of the conditions related to application of energy stored in the storage device.

Accordingly, only the curing of the portion 23b of the protective member 23 moderately progresses, and the portion 23b becomes moderately thin with respect to the portion 23a of the protective member 23. That is, an ideal protective member 23 or a protective member 23 close thereto can be obtained for the purpose of enhancing the uniformity of the thickness of the processed plate-shaped object 1.

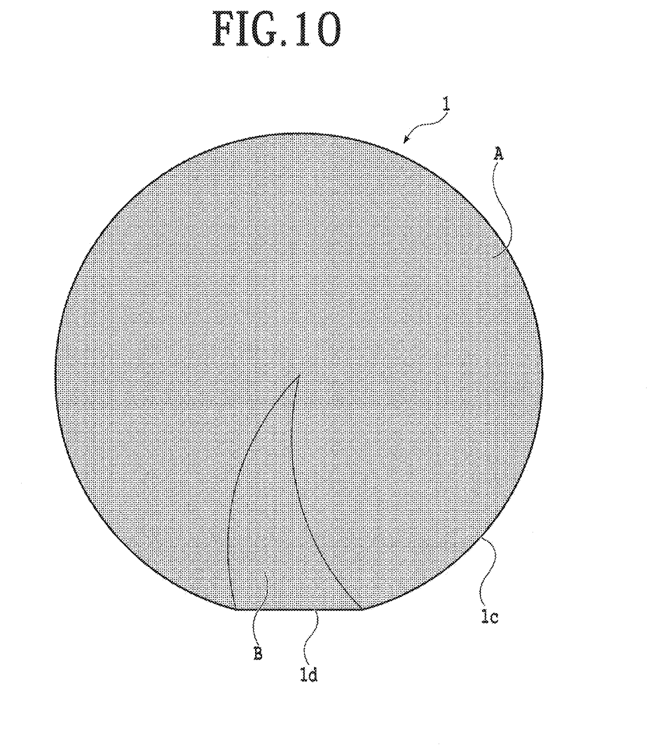

After energy is applied (ultraviolet rays are applied) to the protective member 23, the plate-shaped object 1 is processed to be thinned (plate-shaped object processing step S23). In the present embodiment, the second surface 1b of the plate-shaped object 1 is ground using the grinding unit 131 depicted in FIG. 6, as in the processing of the plate-shaped object for evaluation 11. It should be noted that, since the detailed procedure related to processing of the plate-shaped object 1 and the like are substantially the same as the procedure related to processing of the plate-shaped object for evaluation 11 and the like, the duplicate description thereof is omitted here. FIG. 10 is a plan view for schematically depicting the distribution of the thickness of the processed plate-shaped object 1.

By processing the plate-shaped object 1 with use of the above-described protective member 23 with the energy applied, it is possible to make the thickness of the portion A and the thickness of the portion B approximately equal to each other. It should be noted that, in FIG. 10, the same hatching is applied to the portion A and the portion B to indicate that the thickness of the portion A and the thickness of the portion B are approximately equal to each other. When the plate-shaped object 1 becomes thinner up to a preset thickness, the processing method for a plate-shaped object, which is a part of the manufacturing method for a chip according to the present embodiment, is finished.

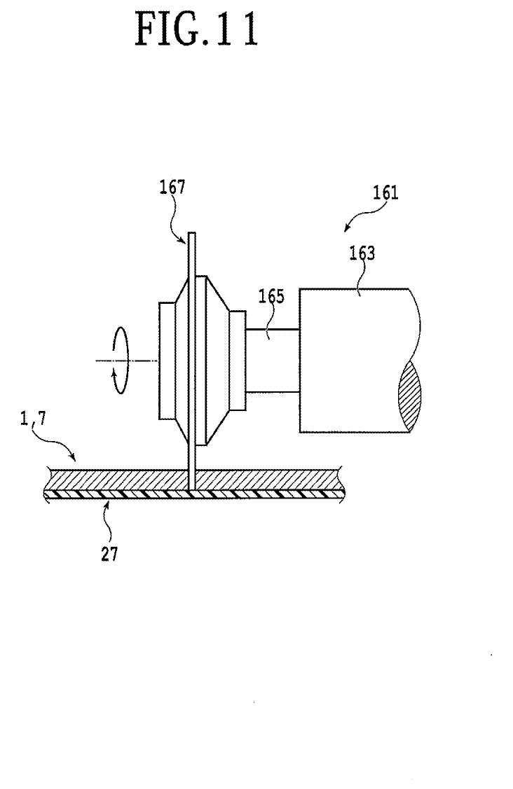

On the other hand, in the manufacturing method for a chip according to the present embodiment, the processed plate-shaped object 1 is subsequently divided (cut) at all the scheduled division lines 3 to manufacture a plurality of chips (chip manufacturing step S3). FIG. 11 is a cross-sectional view for schematically depicting a state in which the plate-shaped object 1 is divided. For example, a cutting unit 161 depicted in FIG. 11 is used for dividing the plate-shaped object 1. It should be noted that the cutting unit 161 may be provided in the processing apparatus 101, or may be provided in a cutting apparatus or the like different from the processing apparatus 101.

As depicted in FIG. 11, the cutting unit 161 is provided with a cylindrical spindle housing 163. A part of a rod-like spindle 165 along the horizontal direction is housed in a space inside the spindle housing 163. An annular cutting blade 167 having a structure in which abrasive grains of diamond or the like are fixed by a bonding agent containing resin and the like is mounted on one end side of the spindle 165 exposed from the spindle housing 163.

A rotation drive source (not illustrated) such as a motor is coupled to the other end side of the spindle 165, and the spindle 165 is rotated about a rotation axis substantially parallel to the horizontal direction by the power generated by the rotation drive source. In addition, the spindle housing 163 is supported by a spindle moving mechanism (not illustrated) including ball screws, and is moved along the horizontal direction and the vertical direction by the power generated by the spindle moving mechanism.

When a plurality of chips are manufactured from the plate-shaped object 1, the plate-shaped object 1 and the spindle housing 163 are moved relative to each other such that the rotated cutting blade 167 is cut into the target scheduled division line 3 of the plate-shaped object 1. At this time, the lower end of the cutting blade 167 is positioned at a position slightly lower than a lower surface of the plate-shaped object 1. A dicing tape 27 or the like is provided on the lower surface of the plate-shaped object 1 if necessary.

Accordingly, the plate-shaped object 1 is subjected to a cutting process and cut at the target scheduled division line 3. By repeating the operation as described above, the plate-shaped object 1 is cut at all the scheduled division lines 3 and divided into a plurality of chips. When a plurality of chips are obtained from the plate-shaped object 1, the manufacturing method for a chip according to the present embodiment is finished.

It should be noted that the specific method for dividing the plate-shaped object 1 is not limited to the method using the above-described cutting process. For example, instead of the cutting process, a method using laser processing for irradiating the plate-shaped object 1 with a laser beam, a method using plasma processing (plasma etching) for exposing the plate-shaped object 1 to plasma gas, or the like may be adopted.

As described above, according to the processing method for a plate-shaped object and the manufacturing method for a chip according to the present embodiment, a freely-selected portion of the protective member is irradiated with ultraviolet rays (energy is applied to the freely-selected portion) such that the thickness (that is, the volume) of a freely-selected portion (portion 23b) of the protective member 23 is made different from at least another portion (portion 23a).

Therefore, when the plate-shaped object 1 is processed to be thinned in a state where the plate-shaped object 1 is held via the protective member 23, the thickness of the processed plate-shaped object 1 at a position corresponding to a freely-selected portion of the protective member 23 is different from the thickness obtained in a case where the plate-shaped object 1 is processed in a state where the protective member 23 is not irradiated with the above-described ultraviolet rays.

That is, according to the processing method for a plate-shaped object and the manufacturing method for a chip according to the present embodiment, when the plate-shaped object 1 is made thin, it is possible to control the thickness of a freely-selected portion of the processed plate-shaped object 1. Further, according to the forming apparatus for a protective member and the processing apparatus 101 of a plate-shaped object according to the present embodiment, the processing method for a plate-shaped object and the manufacturing method for a chip can appropriately be carried out.

It should be noted that the present invention can be carried out in various changed modes without being limited by the description of the above-described embodiment. For example, although the protective member 23 is irradiated with ultraviolet rays as energy in the above-described embodiment, light energy, thermal energy, or the like other than the ultraviolet rays may be adopted as energy to be applied to the protective member 23.

In a case where thermal energy is adopted as energy, for example, a protective member that at least partially includes thermosetting resin such as epoxy resin or polyimide resin can be used. It should be noted that, in the case where the thermal energy is adopted, the thermal energy can be applied to a freely-selected portion of the protective member by a method of controlling the distance between a heat source and the protective member on the basis of the respective positions thereof, the relative speed of movement (including the speed of rotation), or the like, a method of partially covering the protective member with a heat shielding member, or the like.

In addition, although the thickness (volume) of a freely-selected portion of the protective member 23 is made different by application of energy in the above-described embodiment, it is also possible to make a physical property such as hardness (softness) different instead of the thickness (volume) or in addition to the thickness (volume). Although there is no limitation on the kinds of physical properties to be made different by application of energy, if the physical property affecting the hardness of the protective member 23 can be made different by application of energy, the thickness of a freely-selected portion of the processed plate-shaped object 1 can appropriately be controlled on the basis of the above-described principle.

In addition, although the protective member 23 that has been cut out from the tape 21 is irradiated with ultraviolet rays (energy is applied to the protective member 23) in the above-described embodiment, energy may be applied to the corresponding portion of the tape 21 that is the material of the protective member 23. In this case, energy is applied to the corresponding portion of the tape 21 that is the material of the protective member 23 (energy application step), and then, the protective member 23 is formed on the first surface 1a side of the plate-shaped object 1 (protective member formation step).

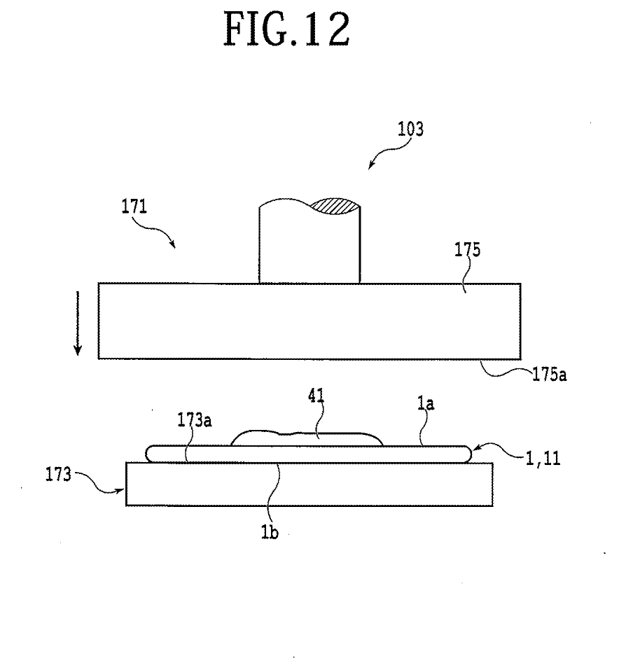

In addition, although the protective member 23 is formed on the first surface 1a side of the plate-shaped object 1 and the protective member for evaluation 25 is formed on the first surface 1a side of the plate-shaped object for evaluation 11 by the method of cutting out the protective member 23 from the tape 21 in the above-described embodiment, the protective member 23 and the protective member for evaluation 25 may be formed by another method such as a method of curing liquid resin. FIG. 12 is a side view for schematically depicting portions related to formation of the protective member in a processing apparatus 103 of a plate-shaped object including a forming apparatus for a protective member according to a modified example.

As depicted in FIG. 12, the processing apparatus 103 according to the modified example includes a protective member forming unit 171 capable of forming the protective member or the protective member for evaluation on the plate-shaped object 1 or the plate-shaped object for evaluation 11. The protective member forming unit 171 is provided with a support table 173 configured so as to be capable of supporting the plate-shaped object 1 or the plate-shaped object for evaluation 11 from the lower side. The plate-shaped object 1 or the plate-shaped object for evaluation 11 is placed on an upper surface 173a of the support table 173.

A pressure plate 175 is arranged above the support table 173. The pressure plate 175 has a substantially flat lower surface 175a. In addition, the pressure plate 175 is supported by a pressure plate lifting mechanism (not illustrated) including ball screws, and is moved along the vertical direction by power generated by the pressure plate lifting mechanism.

When the protective member (or the protective member for evaluation) is formed on the plate-shaped object 1 (or the plate-shaped object for evaluation 11), the plate-shaped object 1 is placed on the support table 173 in such a manner that the second surface 1b of the plate-shaped object 1 is brought into contact with the upper surface 173a of the support table 173. Accordingly, the plate-shaped object 1 is supported by the support table 173 in a state where the first surface 1a faces upward.

Next, in a state where liquid resin 41 is supplied to the first surface 1a of the plate-shaped object 1, the pressure plate lifting mechanism lowers the pressure plate 175, and presses the lower surface 175a of the pressure plate 175 against the liquid resin 41. Accordingly, the liquid resin 41 is pressed and spread over the whole of the first surface 1a side of the plate-shaped object 1. As the liquid resin 41, for example, ultraviolet-curable resin typified by acrylate-based resin, epoxy-based resin, and polyene-polythiol-based resin is used.

After the liquid resin 41 is pressed and spread by the pressure plate 175, the liquid resin 41 is irradiated with ultraviolet rays. It should be noted that, when the whole liquid resin 41 is completely cured, the thickness (volume), hardness (physical property), and the like of a freely-selected portion cannot be adjusted thereafter, and thus, the conditions such as the intensity of ultraviolet rays to be applied and the period of time during which ultraviolet rays are applied are kept within a range in which the liquid resin 41 is not completely cured.

As described above, the protective member (or the protective member for evaluation) is formed on the first surface 1aof the plate-shaped object 1 (or the plate-shaped object for evaluation 11). It should be noted that, in order to easily handle the protective member formed by the liquid resin 41, a base material typified by a film made of resin may be arranged between the lower surface 175aof the pressure plate 175 and the liquid resin 41. In this case, the protective member is formed by the liquid resin 41 cured to some extent and the base material.

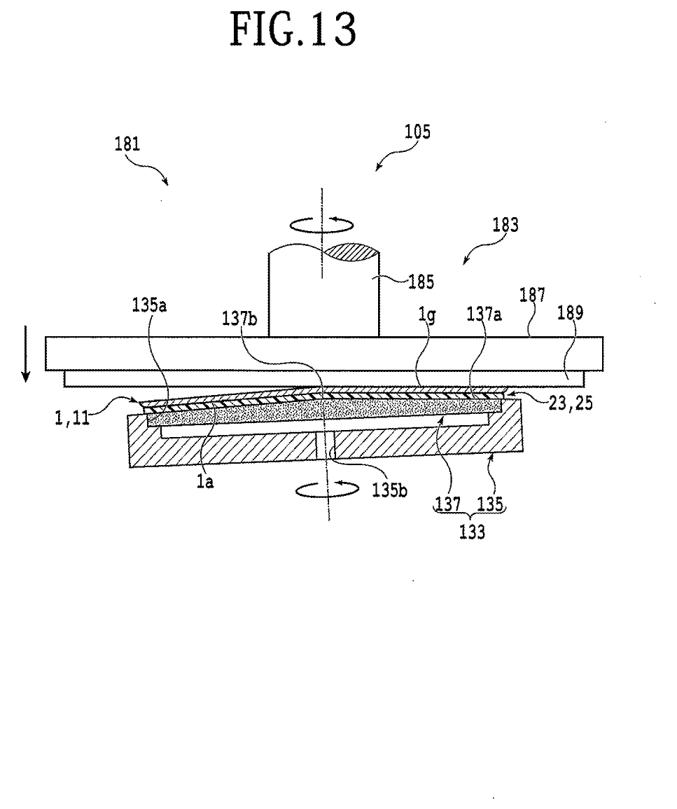

In addition, although the grinding process is adopted in order to make the plate-shaped object 1 (or the plate-shaped object for evaluation 11) thin in the above-described embodiment, a polishing process may be adopted together with the grinding process or instead of the grinding process. FIG. 13 is a cross-sectional view for schematically depicting portions related to processing of the plate-shaped object 1 or the plate-shaped object for evaluation 11 in a processing apparatus 105 of a plate-shaped object according to a modified example.

The processing apparatus 105 depicted in FIG. 13 includes a polishing unit (processing unit) 181 in addition to the above-described grinding unit 131. The polishing unit 181 shares the chuck table 133 for holding the plate-shaped object 1 or the plate-shaped object for evaluation 11 with the grinding unit 131. However, the polishing unit 181 may be provided with its own chuck table independent of the grinding unit 131.

A spindle mechanism 183 for polishing is arranged at a position higher than the chuck table 133. The spindle mechanism 183 includes, for example, a cylindrical spindle housing (not illustrated). A columnar spindle 185 is housed in a space inside the spindle housing. For example, a disk-like mount 187 is provided at the lower end of the spindle 185. A disk-like polishing pad (polishing tool) 189 formed of polymer foam, non-woven fabric, or the like is fixed to a lower surface of the mount 187.

A rotation drive source (not illustrated) such as a motor is coupled to the upper end side of the spindle 185. The polishing pad 189 is rotated about an axis along the vertical direction or an axis slightly inclined with respect to the vertical direction, by the power generated by the rotation drive source. The spindle housing is supported by, for example, a spindle moving mechanism (not illustrated) including ball screws, and the spindle mechanism 183 is moved in the vertical direction by the power generated by the spindle moving mechanism.

The polishing pad 189 is provided with a polishing liquid supply port (not illustrated) capable of supplying liquid for polishing (polishing liquid) such as water or slurry to a portion where the plate-shaped object 1 or the plate-shaped object for evaluation 11 is brought into contact with the polishing pad 189. It should be noted that, instead of the polishing liquid supply port, or together with the polishing liquid supply port, a polishing liquid supply nozzle used for supplying liquid may be provided near the polishing pad 189.

For example, when the plate-shaped object 1 after grinding is to be polished, the chuck table 133 holding the first surface 1a side of the plate-shaped object 1 via the protective member 23 is moved to a position directly below the spindle mechanism 183. It should be noted that, as depicted in FIG. 13, a ground surface 1g generated by grinding of the second surface 1b side of the plate-shaped object 1 is exposed upward here.

Thereafter, the chuck table 133 and the polishing pad 189 are each rotated, and the spindle mechanism 183 is lowered. That is, the polishing pad 189 and the plate-shaped object 1 are moved relative to each other in a direction intersecting the second surface 1b of the plate-shaped object 1 while being mutually rotated. At this time, the liquid for polishing is supplied from the polishing liquid supply port to the plate-shaped object 1, the polishing pad 189, and the like. Then, as depicted in FIG. 13, the polishing pad 189 is brought into contact with the plate-shaped object 1 from the ground surface 1g side, and polishing of the plate-shaped object 1 is started.

When the plate-shaped object 1 becomes thinner up to a preset thickness, the spindle mechanism 183 is lifted, and the polishing pad 189 is separated from the plate-shaped object 1. Accordingly, the polishing of the plate-shaped object 1 is finished. However, the timing of finishing the polishing may be determined on the basis of the period time of the polishing, the flatness of the surface to be polished, or the like, instead of the thickness of the plate-shaped object 1.

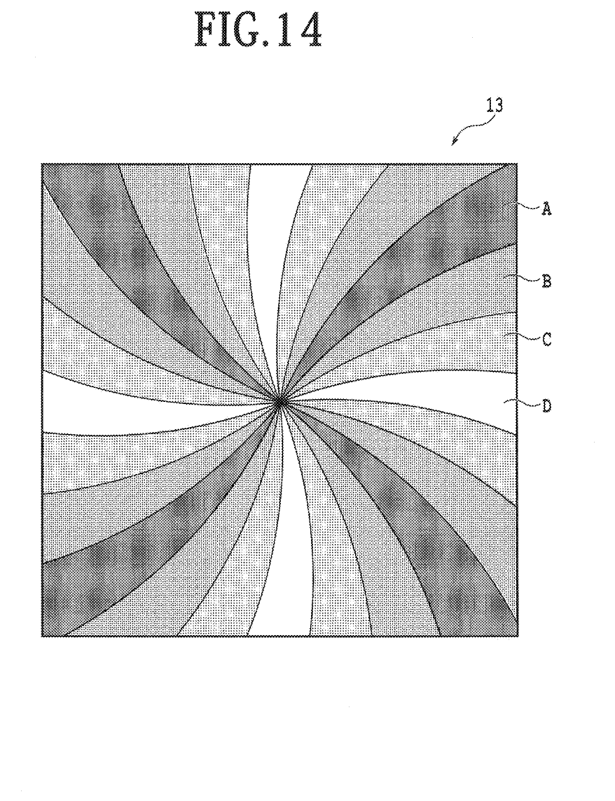

In addition, although the disk-like wafer provided with the cutout portion 1d called an orientation flat is used as the plate-shaped object 1 in the above-described embodiment, the shape of the plate-shaped object to be processed may be a non-disk-like (non-circular) shape. FIG. 14 is a plan view for schematically depicting the distribution of the thickness of a processed plate-shaped object (plate-shaped object for evaluation) 13 formed in a square shape (rectangular shape) in plan view. It should be noted that, in FIG. 14, hatching according to the thickness of the plate-shaped object 13 is applied.

When the square plate-shaped object 13 is ground by the annular grinding wheel 145, as depicted in FIG. 14, the plate-shaped object 13 is the thickest at a portion A that overlaps a straight line corresponding to the diagonal of the square, and is the thinnest at a portion D that is the farthest from the straight line corresponding to the diagonal. More specifically, the portion A is the thickest, followed by a portion B and then a portion C, and the portion D is the thinnest.

Such a difference in thickness occurs because the distance from the center of the plate-shaped object 13, which corresponds to the intersection of the diagonal lines, to the outer edge of the plate-shaped object 13 is the longest at the portion A and the shortest at the portion D. That is, since the grinding load at the portion B is smaller than that at the portion A, the grinding load at the portion C is smaller than that at the portion B, and the grinding load at the portion D is smaller than that at the portion C, there are differences in the ease of grinding among the portion A, the portion B, the portion C, and the portion D.

In this case, it is desirable that the energy (energy per unit area) applied to the protective member be adjusted according to the ease of grinding. Specifically, the portion of the protective member to which the energy is applied (or the corresponding portion of the material) is further divided into a plurality of regions, and different energy (energy per unit area) is allocated as energy to be applied to each region.

In the case of the plate-shaped object 13 depicted in FIG. 14, a portion corresponding to the portion A in the protective member is determined to be a portion to which no energy is applied, and portions corresponding to the portion B, the portion C, and the portion D in the protective member is determined to be portions to which energy is applied. Further, the portion to which the energy is applied in the protective member is divided into a first region corresponding to the portion B, a second region corresponding to the portion C, and a third region corresponding to the portion D.

Then, the energy applied per unit area of the first region, the energy applied per unit area of the second region, and the energy applied per unit area of the third region are set differently from each other. In a case where the protective member is formed of ultraviolet-curable resin whose thickness (volume) decreases as the applied energy increases, the energy applied per unit area of the first region is set to be the smallest. Further, the energy applied per unit area of the second region is set to be the second smallest, and the energy applied per unit area of the third region is set to be the largest.

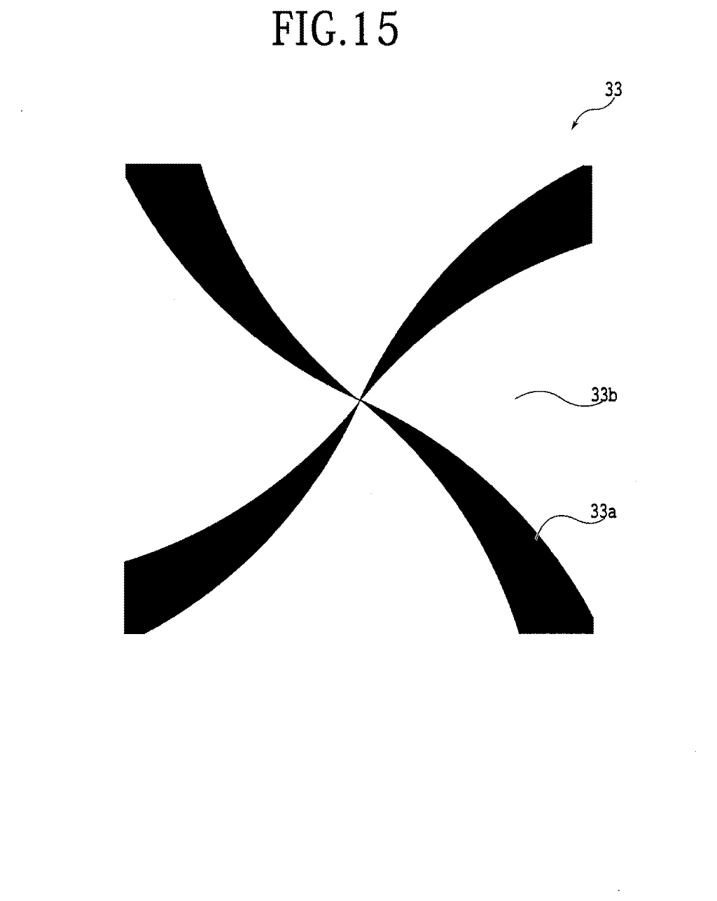

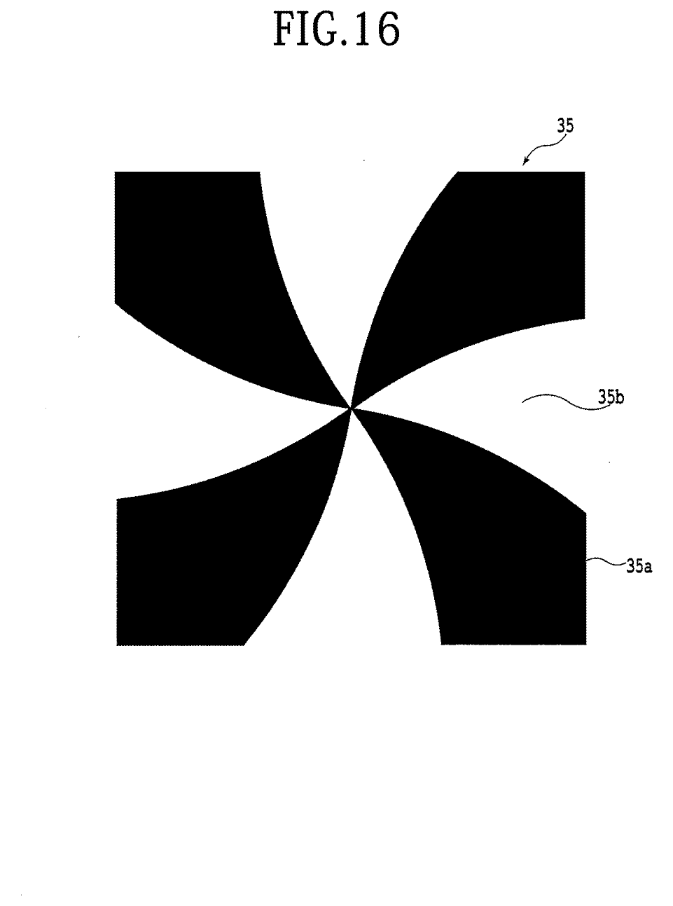

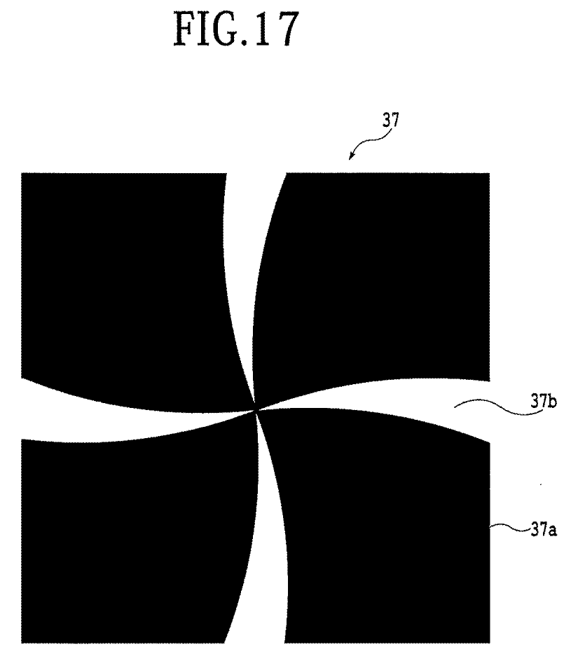

FIG. 15 is a plan view for schematically depicting a first mask 33 used when the protective member is irradiated with ultraviolet rays as energy, FIG. 16 is a plan view for schematically depicting a second mask 35 used when the protective member is irradiated with ultraviolet rays as energy, and FIG. 17 is a plan view for schematically depicting a third mask 37 used when the protective member is irradiated with ultraviolet rays as energy.

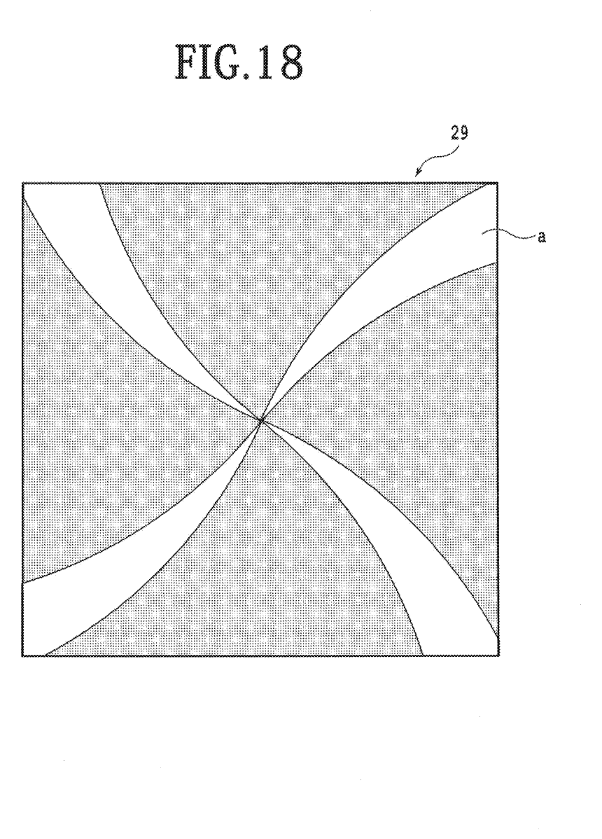

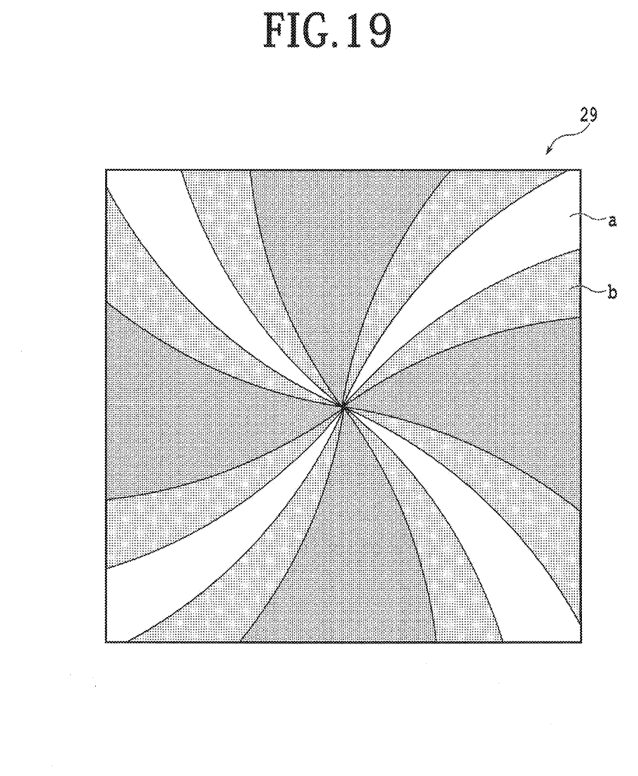

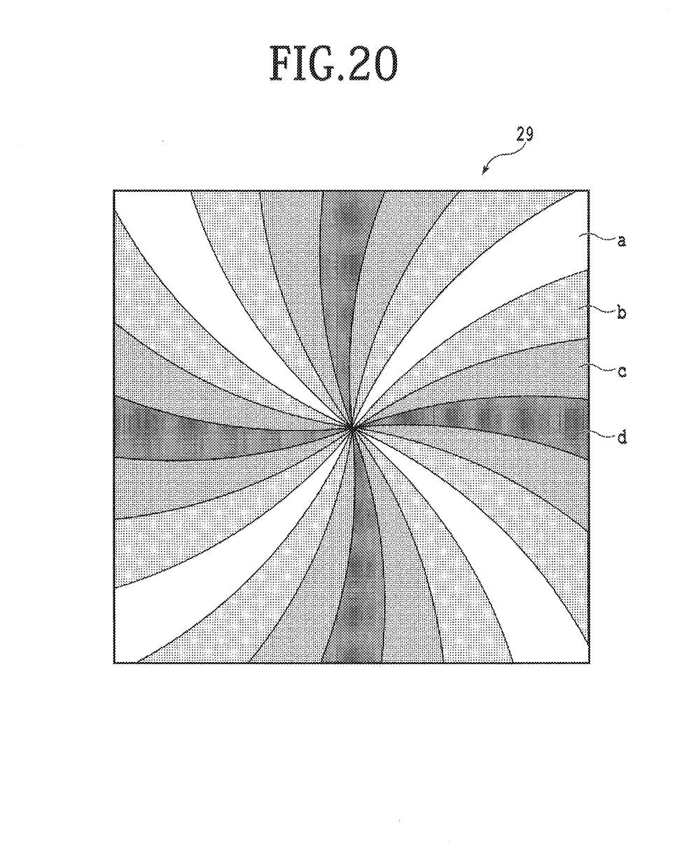

In addition, FIG. 18 is a plan view for schematically depicting the distribution of the thickness of a protective member 29 that has been irradiated with ultraviolet rays with use of the first mask 33, FIG. 19 is a plan view for schematically depicting the distribution of the thickness of the protective member 29 that has further been irradiated with ultraviolet rays with use of the second mask 35, and FIG. 20 is a plan view for schematically depicting the distribution of the thickness of the protective member 29 that has further been irradiated with ultraviolet rays with use of the third mask 37. It should be noted that, in FIG. 18, FIG. 19, and FIG. 20, hatching according to the thickness of the protective member 29 is applied.

When the protective member 29 is irradiated with ultraviolet rays as energy, irradiation with ultraviolet rays with use of the first mask 33 is first performed. That is, the first mask 33 as depicted in FIG. 15 is overlapped with the protective member 29 in a manner similar to that of FIG. 9. The first mask 33 has a shielding portion 33a that does not substantially transmit target ultraviolet rays and a transmission portion 33b that allows target ultraviolet rays to pass through.

The shielding portion 33a is formed in a shape corresponding to a portion a (a shape capable of covering at least a portion a) such that the portion a (see FIG. 18 and other figures) corresponding to the portion A in the protective member 29 is not exposed to ultraviolet rays. In addition, the transmission portion 33bis formed in, for example, a shape obtained by combining a first region b, a second region c, and a third region d such that the first region b (see FIG. 19 and other figures) corresponding to the portion B, the second region c (see FIG. 20) corresponding to the portion C, and the third region d (see FIG. 20) corresponding to the portion D in the protective member 29 are exposed to ultraviolet rays.

Therefore, when the protective member 29 is irradiated with ultraviolet rays in a manner similar to that of FIG. 9 in a state where the first mask 33 is overlapped with the protective member 29, the portion a corresponding to the portion A is not exposed to ultraviolet rays, and the thickness of the portion a does not change, as depicted in FIG. 18. Meanwhile, the first region b corresponding to the portion B, the second region c corresponding to the portion C, and the third region d corresponding to the portion D are exposed to ultraviolet rays, and the thicknesses of the first region b, the second region c, and the third region d become thinner.

It should be noted that the irradiation with ultraviolet rays with use of the first mask 33 is performed under the condition that the ultraviolet-curable resin forming the protective member 29 is not completely cured. This is because, if the ultraviolet-curable resin is completely cured, the ultraviolet-curable resin cannot be cured further by subsequent irradiation with ultraviolet rays with use of the second mask 35 and irradiation with ultraviolet rays with use of the third mask 37.

When the irradiation with ultraviolet rays with use of the first mask 33 is finished, irradiation with ultraviolet rays with use of the second mask 35 is subsequently performed. That is, the second mask 35 as depicted in FIG. 16 is overlapped with the protective member 29 in a manner similar to that of FIG. 9. The second mask 35 has a shielding portion 35athat does not substantially transmit target ultraviolet rays and a transmission portion 35b that allows target ultraviolet rays to pass through.

The shielding portion 35a is formed in a shape corresponding to the portion a and the first region b (a shape capable of covering at least the portion a and the first region b) such that the portion a and the first region b are not exposed to ultraviolet rays in the protective member 29. In addition, the transmission portion 35bis formed in, for example, a shape obtained by combining the second region c and the third region d such that the second region c and the third region d are exposed to ultraviolet rays in the protective member 29.

Therefore, when the protective member 29 is further irradiated with ultraviolet rays in a manner similar to that of FIG. 9 in a state where the second mask 35 is overlapped with the protective member 29, the portion a and the first region b are not exposed to ultraviolet rays, and the thicknesses of the portion a and the first region b do not change, as depicted in FIG. 19. Meanwhile, the second region c and the third region d are exposed to ultraviolet rays, and the thicknesses of the second region c and the third region d become thinner.

It should be noted that the irradiation with ultraviolet rays with use of the second mask 35 is also performed under the condition that the ultraviolet-curable resin forming the protective member 29 is not completely cured. This is because, if the ultraviolet-curable resin is completely cured, the ultraviolet-curable resin cannot be cured further by subsequent irradiation with ultraviolet rays with use of the third mask 37.

When the irradiation with ultraviolet rays with use of the second mask 35 is finished, irradiation with ultraviolet rays with use of the third mask 37 is subsequently performed. That is, the third mask 37 as depicted in FIG. 17 is overlapped with the protective member 29 in a manner similar to that of FIG. 9. The third mask 37 has a shielding portion 37a that does not substantially transmit target ultraviolet rays and a transmission portion 37b that allows target ultraviolet rays to pass through.

The shielding portion 37a is formed in a shape corresponding to the portion a, the first region b, and the second region c (a shape capable of covering at least the portion a, the first region b, and the second region c) such that the portion a, the first region b, and the second region c are not exposed to ultraviolet rays in the protective member 29. In addition, the transmission portion 37bis formed in, for example, a shape corresponding to the third region d such that the third region d is exposed to ultraviolet rays in the protective member 29.

Therefore, when the protective member 29 is further irradiated with ultraviolet rays in a manner similar to that of FIG. 9 in a state where the third mask 37 is overlapped with the protective member 29, the portion a, the first region b, and the second region c are not exposed to ultraviolet rays, and the thicknesses of the portion a, the first region b, and the second region c do not change, as depicted in FIG. 20. Meanwhile, the third region d is exposed to ultraviolet rays, and the thicknesses of the second region c and the third region d become thinner.

By processing the plate-shaped object 13 with use of the protective member 29 provided with the distribution of thickness thus obtained, the uniformity of the thickness of the processed plate-shaped object 13 can be enhanced as in the above-described embodiment.

It should be noted that the protective member 29 having the distribution of the thickness as depicted in FIG. 20 may be realized by a method different from the above-described method using a plurality of masks. For example, if a multi-gradation mask provided with a plurality of shielding portions whose transmittances to target ultraviolet rays are different from each other is used, the irradiation with ultraviolet rays is performed only once, so that the number of steps required for realizing the protective member 29 having the above-described distribution of the thickness can be reduced.

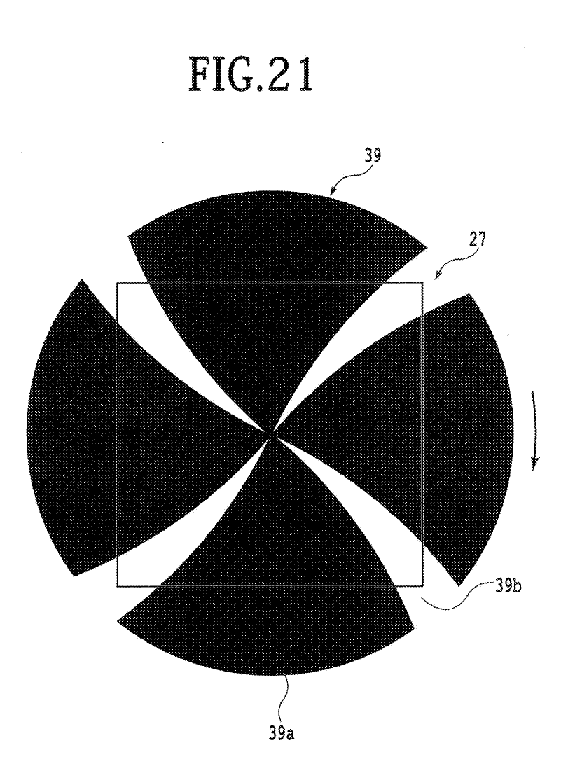

In addition, the protective member 29 having the distribution of the thickness as depicted in FIG. 20 can also be realized by a method of applying ultraviolet rays while displacing one mask. FIG. 21 is a plan view for schematically depicting a state in which a mask 39 is displaced relative to the protective member 29 when the protective member 29 is irradiated with ultraviolet rays as energy.

As depicted in FIG. 21, the mask 39 has a shielding portion 39a that does not substantially transmit target ultraviolet rays and a transmission portion 39b that allows target ultraviolet rays to pass through. The width (diameter) of the mask 39 is larger than the diagonal line of the square of the protective member 29. Further, the transmission portion 39b is formed in, for example, a shape corresponding to each of the above-described portion a, first region b, second region c, and third region d.

When the protective member 29 is irradiated with ultraviolet rays as energy using the mask 39, the mask 39 is supported by a support tool different from the support table for supporting the protective member 29 (and the plate-shaped object 13). Then, in a state where ultraviolet rays are emitted from a light source, for example, a controller rotates at least one of the protective member 29 or the mask 39. The speed of rotation is adjusted in accordance with the position (the orientation and angle) of the transmission portion 39b relative to the protective member 29 such that the period of time during which each region of the protective member 29 is irradiated with ultraviolet rays is appropriate.

Accordingly, the distribution of the thickness similar to that depicted in FIG. 20 can be realized. It should be noted that, instead of applying ultraviolet rays while rotating at least one of the protective member 29 or the mask 39, for example, the irradiation with ultraviolet rays and the rotation and stop (change of the orientation) of at least one of the protective member 29 or the mask 39 may be repeated.

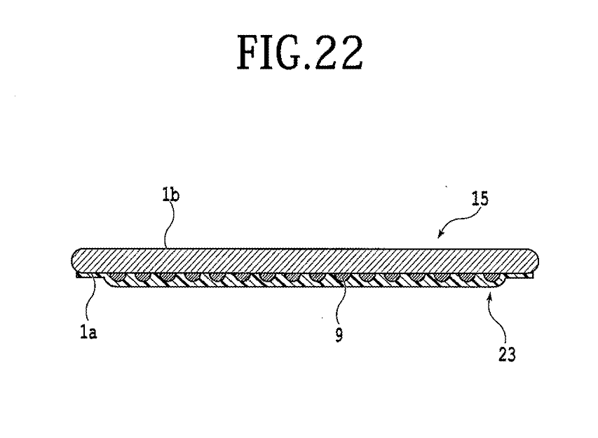

In addition, although the disk-like wafer having no large uneven structure on the first surface 1a side is used as the plate-shaped object 1 in the above-described embodiment, a large uneven structure may be provided on the first surface side of the plate-shaped object to be processed. FIG. 22 is a cross-sectional view for schematically depicting a plate-shaped object 15 on which a bump electrode 9 having an uneven structure on the first surface 1a side is arranged.

In the plate-shaped object 15 of a modified example depicted in FIG. 22, the bump electrode 9 is arranged in a region on the center side that becomes a final product such as a chip, and the bump electrode 9 is not arranged in a region on the outer edge side. Therefore, when the plate-shaped object 15 is processed, the region on the outer edge side tends to be thick as compared with the region on the center side. In such a case, the conditions related to application of energy to the protective member are determined such that processing can easily proceed in the region on the outer edge side of the plate-shaped object 15.

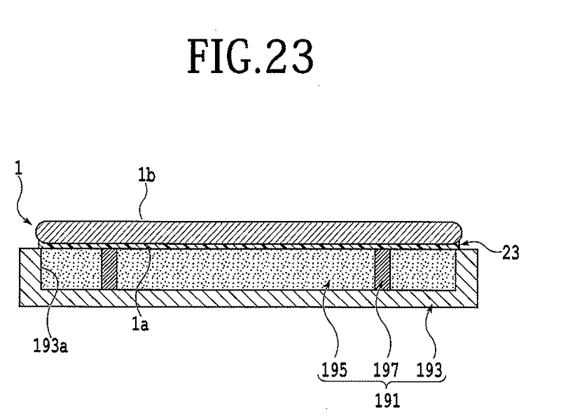

In addition, although it has been described in the above-described embodiment and each modified example that the non-uniformity of the thickness of the processed plate-shaped object is mainly attributable to the shape and structure of the plate-shaped object, the distribution of the thickness of the processed plate-shaped object 1 is also affected by the structure, function, and the like of the chuck table for holding the plate-shaped object 1 during processing. FIG. 23 is a cross-sectional view for schematically depicting a structure of a chuck table 191 according to a modified example.

The chuck table 191 depicted in FIG. 23 includes, for example, a disk-like frame body 193 made of ceramics and the like. A recessed portion 193a having a circular opening at the upper end is formed on the upper surface side of the frame body 193, and a holding plate made of ceramics and the like and configured in a porous disk shape is fixed to the recessed portion 193a.

The holding plate includes, for example, a suction portion 195 having a high porosity and a low-suction portion 197 having a low porosity, and the protective member 23 formed on the plate-shaped object 1 is strongly held at the suction portion 195. Therefore, when the plate-shaped object 1 held by the chuck table 191 is processed, a portion overlapped with the low-suction portion 197 tends to become thinner. In such a case, conditions related to application of energy to the protective member 23 are determined such that processing is difficult to proceed at the portion overlapped with the low-suction portion 197 of the plate-shaped object 1.

In addition, although the plate-shaped object is processed by the grinding wheel 145 and the plate-shaped object being moved relative to each other along the direction of the thickness of the plate-shaped object (the direction perpendicular to the second surface 1b) in the above-described embodiment, the plate-shaped object may be processed by the grinding wheel 145 and the plate-shaped object being moved relative to each other along a direction perpendicular to the direction of the thickness of the plate-shaped object.

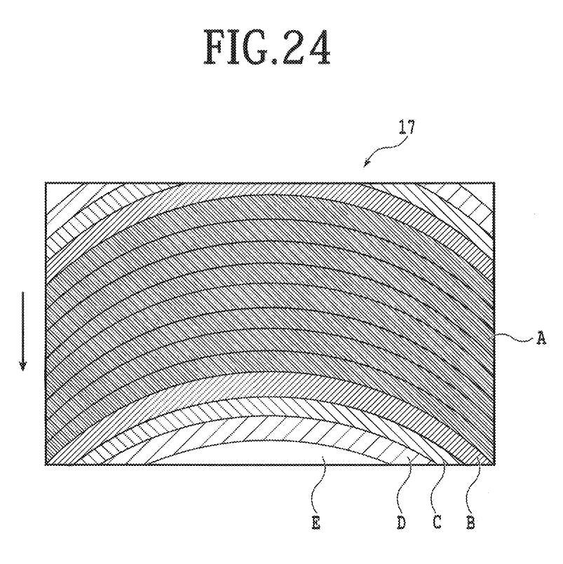

FIG. 24 is a plan view for schematically depicting the distribution of the thickness of a plate-shaped object 17 after grinding (creep feed grinding) by a method according to a modified example. It should be noted that, in FIG. 24, hatching according to the thickness of the plate-shaped object 17 is applied.

In this grinding process, the grinding wheel 145 and the plate-shaped object 17 are moved relative to each other along the direction perpendicular to the direction of the thickness of the plate-shaped object 17 in a state where the lower end of the grinding whetstone 149 is positioned at a height position between a first surface (surface on which the protective member is formed; a lower surface) and a second surface (upper surface) of the plate-shaped object 17. It should be noted that, in this grinding process, the grinding wheel 145 rotates, but the plate-shaped object 17 does not rotate.

In this grinding process, since the grinding wheel 145 passes through the plate-shaped object 17 along the direction of the relative movement (the direction of an arrow in FIG. 24), the area of contact between the grinding wheel 145 and the plate-shaped object 17 becomes small immediately after the processing is started and immediately before the processing is finished. As a result, the plate-shaped object 17 tends to become thinner immediately after the processing is started and immediately before the processing is finished.

For example, in FIG. 24, a portion A of the plate-shaped object 17 is the thickest, followed by a portion B, a portion C, and a portion D, and a portion E is the thinnest. Therefore, in this processing method, conditions related to application of energy to the protective member are determined such that processing is difficult to proceed in the portion processed immediately after the processing is started and the portion processed immediately before the processing is finished.

Incidentally, the most basic technical idea of the present invention is to adjust the thickness of the processed plate-shaped object by making the volume or the physical property of a freely-selected portion of the protective member different from that of at least another portion. Further, this technical idea can be realized without necessarily relying on application of the energy described above. Thus, in the present invention, desired treatment may be performed on the protective member or a material used as the protective member, so as to make the volume or the physical property of a freely-selected portion of the protective member different from that of at least another portion, before or after the protective member is formed.

For example, after the protective member is formed on the first surface side of the plate-shaped object, the target portion of the protective member can be made thinner than other portions by application of mechanical processing such as cutting using a turning tool or grinding. That is, in this case, mechanical processing such as cutting using a turning tool or grinding corresponds to the treatment performed on the protective member.

For example, a pin chuck is used to make the target portion of the protective member thinner than other portions by mechanical processing such as cutting using a turning tool or grinding. The pin chuck is provided with a plurality of pins (projections) for supporting a workpiece (in this case, the plate-shaped object), and sucks the workpiece by applying a negative pressure from a gap between the pins. It should be noted that the pin chuck is configured such that the height of each pin can be adjusted.

When the second surface side of the plate-shaped object is held by the pin chuck in a state where the height of a pin positioned directly below the target portion of the protective member is higher than a reference height (for example, the height of another pin), the height of the target portion of the protective member also becomes higher than the reference height (for example, the height of another portion of the protective member). In this state, if mechanical processing such as cutting using a turning tool or grinding is applied, the target portion of the protective member can easily be made thinner than another portion.

Needless to say, instead of the pin chuck described above, a chuck table provided with a porous holding plate or the like can be used. In this case, for example, as in the case of the above-described pin chuck, the height of the upper surface of the holding plate is partially adjusted. In addition, in this case, the height of the upper surface of the holding plate may substantially be adjusted by partially sandwiching an ultra-thin sheet between the upper surface of the holding plate and the second surface of the plate-shaped object.

In addition, for example, the target portion of the protective member can be made thinner than other portions by applying a local pressure to the target portion of the protective member to crush the target portion after the protective member is formed on the first surface side of the plate-shaped object. In other words, in this case, the application of a local pressure corresponds to the treatment performed on the protective member.

It should be noted that, in a case where the protective member is formed on the first surface side of the plate-shaped object by a method of curing liquid resin, the shape of the lower surface 175a of the above-described pressure plate 175 may be set such that the target portion of the protective member becomes thinner than other portions. Specifically, for example, the shape of the lower surface 175a is set such that the height of the lower surface 175a becomes low at the position corresponding to the target portion as compared with the positions corresponding to other portions of the protective member.

In addition, for example, the target portion of the protective member can be made thinner than other portions (or other portions of the protective member can be made thicker than the target portion) by chemical treatment in which a chemical solution or the like is applied to the target portion of the protective member (or other portions of the protective member) after the protective member is formed on the first surface side of the plate-shaped object. That is, in this case, the chemical treatment for applying a chemical solution or the like corresponds to the treatment performed on the protective member.

Similarly, for example, the target portion of the protective member can be made softer than other portions (or other portions of the protective member can be made harder than the target portion) by chemical treatment in which a chemical solution or the like is applied to the target portion of the protective member (or other portions of the protective member) after the protective member is formed on the first surface side of the plate-shaped object. That is, in this case as well, the chemical treatment for applying a chemical solution or the like corresponds to the treatment performed on the protective member.

In addition, for example, other portions of the protective member can be made thicker than the target portion by coating the other portions of the protective member with liquid resin after the protective member is formed on the first surface side of the plate-shaped object. That is, in this case, the coating with liquid resin corresponds to the treatment performed on the protective member.

In addition, the structures, methods, and the like according to the above-described embodiment and each modified example can appropriately be changed and carried out without departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method for a plate-shaped object, the processing method comprising:
forming a protective member on a first surface side of a plate-shaped object having a first surface and a second surface facing a side opposite to the first surface;
before or after forming the protective member, treating the protective member or a material used as the protective member, so as to make a volume or a physical property of a freely-selected portion of the protective member different from that of at least another portion; and
after forming and treating the protective member, processing the second surface side of the plate-shaped object such that the plate-shaped object becomes thinner in a state where the first surface side of the plate-shaped object is held via the protective member.

2. A processing method for a plate-shaped object, the processing method comprising:
forming a protective member on a first surface side of a plate-shaped object having a first surface and a second surface facing a side opposite to the first surface;
before or after forming the protective member, applying energy to a freely-selected portion of the protective member or a corresponding portion of a material used as the protective member, so as to make a volume or a physical property of the freely-selected portion of the protective member different from that of at least another portion; and
after forming the protective member and applying the energy, processing the second surface side of the plate-shaped object such that the plate-shaped object becomes thinner in a state where the first surface side of the plate-shaped object is held via the protective member.

3. The processing method for a plate-shaped object according to claim 2,
wherein the freely-selected portion of the protective member or the portion of the material includes a first region and a second region different from the first region, and,
in the application of the energy, energy applied per unit area of the first region is made different from that applied per unit area of the second region.

4. The processing method for a plate-shaped object according to claim 2, further comprising:
forming a protective member for evaluation on a first surface side of a plate-shaped object for evaluation having a first surface and a second surface facing a side opposite to the first surface;
after forming the protective member for evaluation, processing the second surface side of the plate-shaped object for evaluation such that the plate-shaped object for evaluation becomes thinner in a state where the first surface side of the plate-shaped object for evaluation is held via the protective member for evaluation;
measuring a thickness of the processed plate-shaped object for evaluation; and
determining the freely-selected portion of the protective member or the portion of the material to which the energy is applied, on a basis of a result obtained by measuring the thickness.

5. The processing method for a plate-shaped object according to claim 3, further comprising:
forming a protective member for evaluation on a first surface side of a plate-shaped object for evaluation having a first surface and a second surface facing a side opposite to the first surface;
after forming the protective member for evaluation, processing the second surface side of the plate-shaped object for evaluation such that the plate-shaped object for evaluation becomes thinner in a state where the first surface side of the plate-shaped object for evaluation is held via the protective member for evaluation;
measuring a thickness of the processed plate-shaped object for evaluation; and
determining the freely-selected portion of the protective member or the portion of the material to which the energy is applied, on a basis of a result obtained by measuring the thickness.

6. A manufacturing method for a chip, the manufacturing method comprising:
forming a protective member on a first surface side of a plate-shaped object having a first surface and a second surface facing a side opposite to the first surface;
before or after forming the protective member, treating the protective member or a material used as the protective member, so as to make a volume or a physical property of a freely-selected portion of the protective member different from that of at least another portion;
after forming and treating the protective member, processing the second surface side of the plate-shaped object such that the plate-shaped object becomes thinner in a state where the first surface side of the plate-shaped object is held via the protective member; and
after processing the second surface side of the plate-shaped object, manufacturing a chip by dividing the plate-shaped object.

7. A manufacturing method for a chip, the manufacturing method comprising:
forming a protective member on a first surface side of a plate-shaped object having a first surface and a second surface facing a side opposite to the first surface;
before or after forming the protective member, applying energy to a freely-selected portion of the protective member or a corresponding portion of a material used as the protective member, so as to make a volume or a physical property of the freely-selected portion of the protective member different from that of at least another portion;
after forming the protective member and applying the energy, processing the second surface side of the plate-shaped object such that the plate-shaped object becomes thinner in a state where the first surface side of the plate-shaped object is held via the protective member; and
after processing the second surface side of the plate-shaped object, manufacturing a chip by dividing the plate-shaped object.

8. The manufacturing method for a chip according to claim 7,
wherein the freely-selected portion of the protective member or the portion of the material includes a first region and a second region different from the first region, and,
in the application of the energy, energy applied per unit area of the first region is made different from that applied per unit area of the second region.

9. The manufacturing method for a chip according to claim 7, further comprising:
forming a protective member for evaluation on a first surface side of a plate-shaped object for evaluation having a first surface and a second surface facing a side opposite to the first surface;
after forming the protective member for evaluation, processing the second surface side of the plate-shaped object for evaluation such that the plate-shaped object for evaluation becomes thinner in a state where the first surface side of the plate-shaped object for evaluation is held via the protective member for evaluation;
measuring a thickness of the processed plate-shaped object for evaluation; and
determining the freely-selected portion of the protective member or the portion of the material to which the energy is applied, on a basis of a result obtained by measuring the thickness.

10. The manufacturing method for a chip according to claim 8, further comprising:
forming a protective member for evaluation on a first surface side of a plate-shaped object for evaluation having a first surface and a second surface facing a side opposite to the first surface;
after forming the protective member for evaluation, processing the second surface side of the plate-shaped object for evaluation such that the plate-shaped object for evaluation becomes thinner in a state where the first surface side of the plate-shaped object for evaluation is held via the protective member for evaluation;
measuring a thickness of the processed plate-shaped object for evaluation; and
determining the freely-selected portion of the protective member or the portion of the material to which the energy is applied, on a basis of a result obtained by measuring the thickness.

11. A forming apparatus for a protective member, the forming apparatus comprising:
a protective member forming unit that forms a protective member on a first surface side of a plate-shaped object in a state where a second surface side of the plate-shaped object having a first surface and a second surface facing the side opposite to the first surface is held;
an energy applying unit that applies energy to a freely-selected portion of the protective member so as to make a volume or a physical property of the freely-selected portion of the protective member different from that of at least another portion in a state where the second surface side of the plate-shaped object on the first surface side of which the protective member is formed is held; and
a controller that controls an operation of at least the energy applying unit,
wherein the controller stores a condition for applying energy to the freely-selected portion of the protective member and controls an operation of the energy applying unit on a basis of the stored condition to apply energy to the freely-selected portion of the protective member.

12. A processing apparatus for a plate-shaped object, the processing apparatus comprising:
an energy applying unit that applies energy to a freely-selected portion of a protective member provided on a first surface side of a plate-shaped object, so as to make a volume or a physical property of the freely-selected portion of the protective member different from that of at least another portion in a state where a second surface side of the plate-shaped object having a first surface and a second surface facing the side opposite to the first surface is held;
a processing unit that processes the second surface side of the plate-shaped object such that the plate-shaped object becomes thinner in a state where the first surface side of the plate-shaped object is held via the protective member; and
a controller that controls an operation of at least the energy applying unit,
wherein the controller stores a condition for applying energy to the freely-selected portion of the protective member and controls an operation of the energy applying unit on a basis of the stored condition to apply energy to the freely-selected portion of the protective member.

13. The processing apparatus for a plate-shaped object according to claim 12, further comprising:
a protective member forming unit that forms a protective member on the first surface side of the plate-shaped object in a state where the second surface side of the plate-shaped object is held.
